(19) United States
(12) Patent Application Publication
(10) Pub. No.: US 2022/0074625 A1
(43) Pub. Date: Mar. 10, 2022

(54) OPTICAL SYSTEM FOR MANIPULATION AND CONCENTRATION OF DIFFUSE LIGHT AND METHOD OF PRODUCING SUCH

(71) Applicant: UPPLENS AB, Uppsala (SE)

(72) Inventor: Ilia KATARDJIEV, Uppsala (SE)

(73) Assignee: UPPLENS AB, Uppsala (SE)

(21) Appl. No.: 17/417,857

(22) PCT Filed: Dec. 20, 2019
(86) PCT No.: PCT/SE2019/051337

§ 371 Date: Jun. 24, 2021

(30) Foreign Application Priority Data
Dec. 27, 2018 (SE) 1851670-8
May 15, 2019 (SE) 1950581-7

(51) Int. Cl. F24S 23/70; G02B 19/00; G02B 5/08

(52) U.S. Cl. CPC F24S 23/82; G02B 19/0042; G02B 26/023; G02B 5/0816; G02B 19/0028

(57) ABSTRACT

The present invention relates to an optical system for concentrating incoming light comprising a plurality of concentrating optical elements (100) with a front surface (102) arranged to receive incoming light and a back surface (103) arranged to exit light, wherein the front surface is larger than the back surface. Adjacent concentrating optical elements are separated by gaps (101) and the refractive index of the material in a concentrating optical element is higher than the refractive index of the gap. The geometry of the concentrating optical elements is optimized to enhance the light concentration.

### FIELD OF THE INVENTION

The present invention relates to the field of optics and in particular manipulating diffused and/or directional light. In particular the invention provides an optical system concentrating direct and indirect sunlight and thereby facilitates light harvesting systems.

### BACKGROUND

Employing total internal reflection is a promising approach for the design of non-collimated light manipulators and concentrators. Cherney et al¹ have proposed a design where a focusing optical unit consists of refractive elements arranged on a curved surface having a geometrical line (or point) of focus such that the refractive section of the concentrator is positioned at some significant distance from the focal plane in order to increase light concentration at the expense of divergence losses with distance. The acceptance angle and transmission coefficients of both the refractive elements and the concentrator are not defined and, most importantly, rejection losses caused by the escape-cone effect are not accounted for and which losses are highly detrimental to such optical systems. Concentration coefficients of around 9 are reported.

### SUMMARY OF THE INVENTION

The object of the invention is to provide optical system for concentrating incoming light that overcomes the drawback of prior art systems.

This is achieved by an optical system for concentrating incoming light as defined by claim 1, a concentrating light harvesting system as defined in claim 17, a transparent illumination sheet as defined in claim 27, and a concentrating optical element as defined in claim 30.

The optical system for concentrating incoming light in a predetermined wavelength interval according to the invention comprises of a plurality of individual optical elements forming a body of optical elements, the individual optical elements comprising a front surface, a back surface, and a peripheral surface, wherein the peripheral surface extends from the front surface to the back surface. At least a portion of the individual optical elements are concentrating optical elements made of first optically transparent materials and for which the front surface is arranged to receive the incoming light, and the back surface and the peripheral surface are arranged to exit light, and wherein the area of the front surface area is larger than the area of the back surface of the same concentrating optical element. The concentrating optical elements are separated from adjacent individual optical elements by gaps extending in the directions of the peripheral surfaces and the gaps comprise second optically transparent materials. The optical system comprises
an input acceptance aperture for receiving the incoming light, the input acceptance aperture formed by at least a major portion of the combined front surfaces of the individual optical elements;
an exit aperture for exiting light from the optical system, the exit aperture formed by at least a major portion of the combined back surfaces of the individual optical elements;
a boundary surface of the body of the optical elements formed by the outermost sections of the peripheral surfaces of the outermost optical elements;
a reflective enclosure enclosing at least a portion of the boundary surface of the body of optical elements and provided with a reflective surface facing the enclosed body of optical elements,
and wherein:
the input acceptance aperture has a larger area than the exit aperture; and
the refractive index of one first optically transparent material of one concentrating optical element is higher than the refractive index of one second material optically transparent of at least one gap abutting the same one concentrating optical element.

The optical system may comprise different concentrating optical elements with different optical transparent materials with different refractive indices, all satisfying the conditions described above with regards to adjacent gaps.

According to one aspect of the invention the gap is filled with a gas.

According to one aspect of the invention each concentrating optical element is a polyhedron comprising a plurality of facets and wherein a first set of facets are facets belonging to the front surface, a second set of facets are facets belonging to the back surface and the peripheral surface of the concentrating optical element, and wherein the concentrating optical element has at least one pair of facets belonging to the second set of facets and comprising a first facet and a second facet. The first and the second facet are arranged to be in direct visibility with each other and arranged with an internal angle, ζ, between the first and second facet of the pair of facets, the internal angle, ζ, selected to be in the interval:

0<ζ<2.5a sin[n₂/n₁]

wherein n₁ is the refractive index of the concentrating optical element material, the first optically transparent material and n₂ is the refractive index of the gap material, the second optically transparent material, the refractive indices associated with the predetermined wavelength range of the optical system. Preferably the internal angle, ζ, is selected to be in the interval

0<ζ<2a sin[n₂/n₁]

and even more preferably in the interval

π/2−a sin[n₂/n₁]<ζ<2 a sin[n₂/n₁].

According to one aspect of the invention the optical system comprises a first section with first reflective properties and at least a second section with second reflective properties. The first section of the reflective enclosure may comprise a metallic mirror and the second section a Bragg mirror and wherein the first section is provided adjacent to the input acceptance aperture and the second section adjacent to the exit aperture. The reflective enclosure may least partly be a layered structure wherein a first set of layers forms a metallic mirror and a second set of layers forms a Bragg reflector, the second set of layers provided on top of the first set of layers.

According to one aspect of the invention at least one concentrating optical element comprises a major sub-element and at least one minor sub-element, the major sub-element partly separated from the minor sub-element by at least one internal gap, the internal gap extending from the front surface in the direction towards the back surface but not extending all the distance to the back surface so that a portion of the concentrating optical element adjacent to the back surface is common to both the major sub-element and the minor sub-elements. Preferably, the refractive index of the concentrating optical element is higher than the refractive index of the internal gap.

According to one aspect of the invention the concentrating optical element comprises a shell of a first optically transparent material defining the geometrical shape of the concentrating optical element and defining a cavity in the interior of the concentrating optical element and a filler of a third optically transparent material filling the cavity of the concentrating optical elements, for example but not limited to an optically transparent liquid comprising one of or a combination of water, alcohols, diols, and triols.

According to one aspect of the invention the optical system comprises a top protective transparent screen provided in contact with the combined front surfaces of the concentrating optical elements and spanning over the input acceptance aperture and joining the reflective enclosure at the circumference of the optical system.

According to one aspect of the invention the gaps between adjacent concentrating optical elements are defined by spacers of predetermined thicknesses, the spacers provided on the peripheral surfaces of at least a portion of concentrating optical elements. The spacers may be provided as protrusions from the peripheral surface of the corresponding concentrating optical elements. Alternatively, spacers are formed by one part provided as a protrusion from a first concentrating optical element and a matching second part being provided as a protrusion from an adjacent second concentrating optical element. Still another alternative is to provide the spacers as individual objects separate from the corresponding concentrating optical elements.

According to one aspect of the invention concentrating light harvesting system are provided comprising the above described optical system or a plurality of optical systems in combination with a light absorber or light absorbers. The light absorber is arranged beneath the back surface of the optical system. Light absorbers can for example be solar cells giving a concentrating photovoltaic system or a thermal light absorber giving a concentrating solar thermal system or a combination of them.

According to one aspect of the invention a concentrating photovoltaic system is provided comprising at least one optical system as described above, and at least one photovoltaic cell optically matched and positioned in the vicinity of the exit aperture of the optical system. The concentrating photovoltaic system may be provided as an array of a plurality of optical systems and photovoltaic solar cells positioned in the vicinity of the exit aperture of each optical system. A thermal insulator covering all surfaces of the concentrating photovoltaic system except the input acceptance aperture, may be provided.

According to one aspect of the invention a concentrating solar thermal system is provided comprising at least one optical system as described above, and at least one light absorber attached to the back side of the exit aperture of the optical system, and wherein the light absorber is in thermal contact with a thermal transport system.

A combined concentrating solar thermal system and concentrating photovoltaic system comprising a concentrating photovoltaic system may be envisaged.

According to one aspect of the invention the above described systems further comprises a sun tracking system. According to one aspect of the invention the above described systems further comprises a movable shading system which in a closed position is arranged to cover at least a portion of the input acceptance aperture or apertures. According to one aspect of the invention the above described systems further comprises an emergency shading system that is arranged to apply a non-transparent substance on the input acceptance aperture or apertures. According to one aspect of the invention the above described systems further comprises a shutter mechanism provided between the optical system and the light absorber, the shutter mechanism arranged to in its closed position prevent light existing the optical system from reaching the light absorber.

According to one aspect of the invention a transparent illumination sheet suitable for directional illumination by light is provided and comprises a plurality of concentrating optical elements made of a material of a first refractive index and arranged in a two-dimensional array, the central axis of the concentrating optical elements arranged to be essentially parallel, the concentrating optical elements comprising a front surface, a back surface, and a peripheral surface, wherein the peripheral surface extends from the front surface to the back surface, and the area of the front surface area is larger than the area of the back surface of the same concentrating optical element. The concentrating optical elements are separated from adjacent individual optical elements by a surrounding material with a second refractive index. The refractive index of the material of the concentrating optical elements is higher than the refractive index of the material of at least one gap abutting the same concentrating optical element; and wherein the concentrating optical element is a polyhedron comprising a plurality of facets, wherein a first set of facets are facets belonging to the front surface, a second set of facets are facets belonging to the back surface and the peripheral surface of the concentrating optical element, and wherein the concentrating optical element has at least one pair of facets belonging to the second set of facets and comprising a first facet and a second facet, the first and second facet arranged to be in direct visibility with each other and arranged with an internal angle, ζ, between the first and second facet of the pair of facets, the internal angle, ζ, selected to be in the interval

0<ζ<2.5a sin[n₂/n₁]

wherein n₁ is the refractive index of the concentrating optical element material and n₂ is the refractive index of the surrounding material, the refractive indices associated with the predetermined wavelength range of the optical system. Preferably:

0<ζ<2a sin[n₂/n₁]

and even more preferably

π/2−a sin[n₂/n₁]<ζ<2 a sin[n₂/n₁].

According to one aspect of the invention the concentrating optical elements are triangular prisms with an apex angle α, selected so that

α=π−2a sin[n₂/n₁]±25%

and wherein the prisms are sectioned at appropriate intervals by vertical gaps forming an angle ζ with at least one sidewall of the prism such that

π/2−a sin[n₂/n₁]<ζ<2 a sin[n₂/n₁].

According to one aspect of the invention a concentrating optical element provided which comprises a plurality of facets wherein the normal vector to each facet points towards the bulk of the optical element, and wherein a first set of facets are facets belonging to the front surface, a second set of facets are facets belonging to the back surface and the peripheral surface of the concentrating optical element, the concentrating optical element being formed of a first material having a first refractive index and adapted to be used surrounded on at least the peripheral surface by a second material having a second refractive index. At least one pair of facets belongs to the second set of facets and comprising a first facet and a second facet, the first and second facet arranged to be in direct visibility with each other and arranged with an internal angle, ζ, between the first and second facet of the pair of facets, the internal angle, ζ, selected to be in the interval

0<ζ<2.5a sin[n₂/n₁]

wherein n₁ is the refractive index of the concentrating optical element material and n₂ is the refractive index of the surrounding material, the refractive indices associated with the predetermined wavelength range of the optical system. Preferably

0<ζ<2a sin[n₂/n₁]

and even more preferably

π/2−a sin[n₂/n₁]<ζ<2 a sin[n₂/n₁].

With respect to harvesting solar energy one advantage with the present advantage is that it eliminates the need for tracking the sun, thus reducing significantly the cost of concentrating photovoltaic (CPV) and concentrating solar power (CSP) systems opening the way for the commercialization of the latter in both the consumer and the industrial power generation markets. Rooftop CPV and CSP systems are now feasible by using arrays of concentrators arranged in a panel configuration. In industrial applications crude (low cost) tracking may still be implemented for the sole purpose of maximizing the exposure area of the panels to direct sunlight. Concentration coefficients of several hundreds and more are readily achievable. This allows the use of more sophisticated multi-junction solar cells with an efficiency typically exceeding 30%. Another advantage of the invention is that the light absorbers (solar cells, etc) may now be thermally insulated from the ambient allowing for the utilization of the residual (waste) heat. Thus, rooftop CPV systems may now represent true cogeneration systems for both electricity and heat generation. Such cogeneration panels may also be used in the construction industry as building elements in both façades and roofs in combination with heat reservoirs.

A further advantage of the invention is that high concentration coefficient of the concentrator allows the generation of high grade heat by CSP systems and hence the invention is suitable for both power generation and long term chemical energy storage. Another possible use relates to large scale water desalination and purification using solar power. Other examples include materials processing, e.g. surface modification through heat treatment, deposition of thin film coatings, evaporation, welding, laser pumping, etc. Another feature of the concentrator is that the concentrated light may be confined in an angular range suitable for waveguiding. This allows their use in illumination applications, such as lighting of living and office spaces, greenhouses, etc.

In the following, the invention will be described in more detail, by way of example only, with regard to non-limiting embodiments thereof, reference being made to the accompanying drawings.

The present invention is not limited to the below-described embodiments. Various alternatives, modifications and equivalents may be used. Therefore, the embodiments should not be taken as limiting the scope of the invention, which is defined by the appending claims.

### DESCRIPTION OF DRAWINGS

FIG. 1. Schematic of a diffuse light concentrator.

FIG. 2a. Propagation of extrinsic rays through an optical element.

FIG. 2b. Propagation of intrinsic rays through an optical element.

FIG. 3a. Schematic illustration of the maximum lateral spread of refracted rays upon exit from an optical element.

FIG. 3b. Ray bifurcation as a result of sequential reflection/refraction events at the exit-walls.

FIG. 3c. Locus of refracted rays incident in the plane of the front surface.

FIG. 3d. Trajectory of an extrinsic ray incident in the plane of the front surface.

FIG. 3e. Illustration of the refractive cone at the point of ray incidence.

FIG. 3f. Illustration of the rays propagating through total internal reflection in the cross-section of an edge.

FIG. 3g. Illustration of the ray sector and ray sector image after rotation.

FIG. 3h. Schematic illustration of an edge bandgap.

FIG. 3i. Illustration of the optimal edge angle.

FIG. 3j. Illustration of a horizontal bandgap in 2D.

FIG. 3k. Illustration of the rays propagating through total internal reflection in the cross-section of an edge with curved exit-walls.

FIG. 3l. Cross-sections of basic edge types with curved exit-walls.

FIG. 3m. Example of tapering the tip of an optical element.

FIG. 4a. Schematic illustration of the overlap of the diffuse element images of two optical elements in close proximity.

FIG. 4b. Schematic illustration of the principle of light concentration.

FIG. 4c. Schematic illustration of collective focusing effects.

FIG. 4d. Schematic illustration of the focusing effect of the peripheral mirrors.

FIG. 4e. Schematic of the top view of a concentrator with triangular optical elements.

FIG. 5a. Example of nesting of hexagonal optical elements.

FIG. 5b. Example of nesting of triangular optical elements.

FIG. 5c. Example of nesting of triangular optical elements.

FIG. 6a. Example of positioning of spacers on the exit-walls: anti-symmetrically positioned spacers, front view (left), side view (right).

FIG. 6b. Example of positioning one symmetric and one asymmetric spacers, front view (left), side view (middle), top view (right).

FIG. 6c. Example of interlocking, anti-symmetrically positioned spacers.

FIG. 6d. Assembly of the peripheral mirrors together with a temporary alignment element.

FIG. 6e. Self-assembly of the concentrator by sequential insertion of the optical elements.

FIG. 6f. Definition of a protective screen.

FIG. 6g. Schematic assembly of a retractable mirror (shutter).

FIG. 6h. Final encapsulation with an exit plate.

FIG. 7a. Positioning of optical elements with spacers on a planar fixture.

FIG. 7b. Folding of the optical elements on a thermally compliant planar fixture.

FIG. 7c. Assembly of the peripheral mirrors along with the shutter and exit plate.

FIG. 7d. Final assembly of the concentrator by insertion of the optical elements followed by definition of a protective screen.

FIG. 8a. Example of definition of sacrificial spacers at the tip of the optical elements.

FIG. 8b. Manipulating the optical elements into position followed by the definition of a protective screen.

FIG. 8c. Planarization of the tips of the optical elements.

FIG. 8d. Fixation of the tips of the optical elements by bonding with the exit plate.

FIG. 8e. Removal of the sacrificial spacers.

FIG. 9a. Fabrication of the exit-walls of hollow optical elements.

FIG. 9b. Assembly of the exit-walls (shell) of a hollow optical element (leftmost) subsequently filled with an optical liquid and encapsulated with a lid/front surface (rightmost).

FIG. 10. Schematic illustration of nesting in a hexagonal parent optical element: side view (left) and top view (right).

FIG. 11. Schematic illustration of the fabrication of an optical element with gaps made of a solid material.

FIG. 12a. Schematic illustration of achieving high light concentration with a single concentrator and subsequent parallelization.

FIG. 12b. Schematic illustration of achieving high light concentration with cascaded concentrators.

FIG. 13a. A CPV cell comprising of a diffuse light concentrator and a solar cell.

FIG. 13b. A CPVT cell comprising of a thermally insulated CPV cell connected to a heat transport system.

FIG. 13c. A CST cell comprising of a diffuse light concentrator, an insulating exit plate and a light absorber connected to a heat transport system.

FIG. 14. Schematic illustration of a water desalination system.

FIG. 15. Schematic illustration of a diffuse light transformer.

FIG. 16a. Encapsulation of a diffuse light transformer with a back sheet.

FIG. 16b. Encapsulation of a diffuse light transformer by planarization.

FIG. 16c. A schematic of a diffuse light transformer with a large apex angle.

FIG. 17a. A schematic illustration of a rolling wheel with triangular grooves.

FIG. 17b. Direction of roll along the surface of the transparent sheet.

FIG. 17c. A schematic illustration of a wheel cutter.

FIG. 18. Schematic illustration of fabrication by moulding.

FIG. 19. Schematic illustration of spacer placement into triangular grooves.

FIG. 20a. Calculated propagation losses as a function of concentration coefficient.

FIG. 20b. Calculated rejection losses as a function of concentration coefficient.

### DETAILED DESCRIPTION

Principle of Operation

The object of this invention is the design of optical elements and optical devices for manipulating and concentrating a diffuse light flux having an arbitrary intensity distribution in the range

$$( - \frac{π}{2} , + \frac{π}{2} )$$

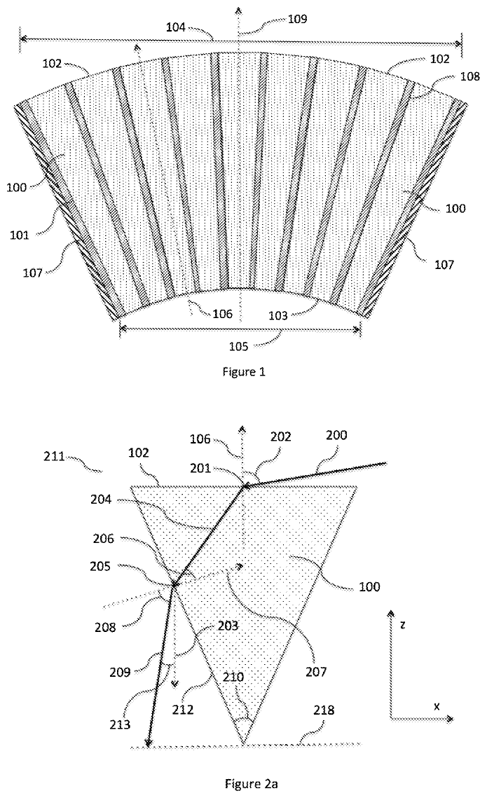

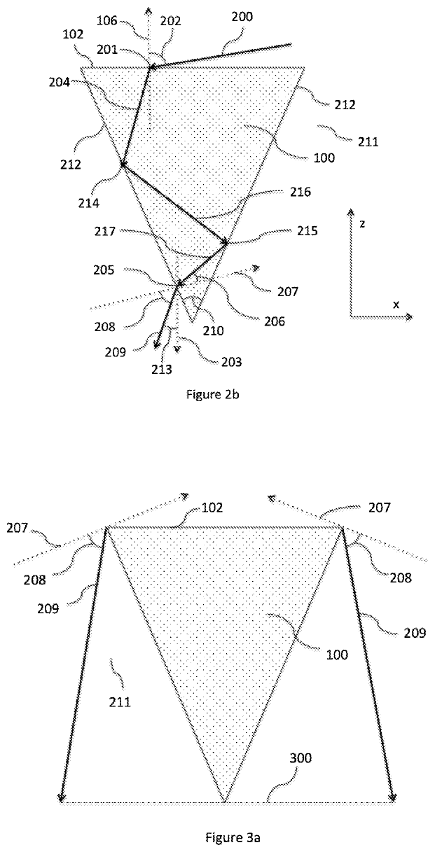

with respect to a given axis and exhibiting large transmission coefficients. Thus, in one embodiment, the proposed light concentrators represent optical devices consisting of a multitude of optical elements 100 made of an optically transparent material of relatively high refractive index n₁ and physically separated from each other by small gaps 101 filled with an optical material of lower refractive index n₂, i.e. n₂<n₁, and bounded around the periphery by a mirror structure 107 facing the optical elements as illustrated in FIG. 1 in 2D. The optical elements have a front surface 102, a back surface 103 and a peripheral surface 108 which is bounded by the front surface 102 and the back surface 103. The term “surface” here is used to denote a boundary element and each of the three surface types (front, peripheral and back) may represent an arbitrary set of planar and curved surfaces as well as edges between them. Each optical element has an axis 106 associated with it, with respect to which the angular distribution of the incident light flux is defined. The area of the back surface 103 may be diminishing, i.e. it may represent a sharp tip or a wedge with an arbitrarily small radius. A plane perpendicular to axis 106 and lying outside the optical element but in intimate proximity with the back surface 103, referred to as the focal plane 218 (in FIG. 2a) of the optical element is also associated with the latter. The projected area of the front surface 102 onto the focal plane is larger than the projected area of the back surface 103 onto the focal plane meaning that the area of the cross-section parallel to the focal plane 218 generally decreases with decreasing the distance from the focal plane 218. The area 104 consisting of the projected areas of the front surfaces of all optical elements along with the gaps between them onto a plane perpendicular to a central axis 109 of the concentrator defines the effective acceptance area of the concentrator (also called “diffuse source” or “input aperture”). The corresponding projected area 105 on the back side defines the output of the concentrator (called “diffuse source image” or “exit aperture”). The ratio between the two areas multiplied by the transmission coefficient of the optical system defines the light concentration coefficient in “number of suns”. As argued in detail below, the design of the optical elements 100 is such that an optical element projects the predominant fraction of a light flux having an arbitrary distribution in the range

$$( - \frac{π}{2} , + \frac{π}{2} )$$

relative to the axis 106 and entering the optical element through the front surface 102 onto a limited area in the focal plane 218. In this way, each optical element channels a diffuse light flux from its front surface 102 towards the exit aperture 105 of the concentrator. In addition, in order to prevent light flux from straying sideways suitable mirrors 107 are placed on the periphery of the concentrator to confine stray light back into the core of the latter.

The actual dimensions of the individual optical elements are determined by the specific application but always obey the laws of geometrical optics, that is, their dimensions are large enough to consider light propagation in them as straight lines (geometrical rays). Typically but not exclusively, the height of the optical elements (defined as the largest dimension along axis 106) lies in the range 0.1-50 cm. Analogously, the width of the gaps 101 is limited from below such that light propagation in them also obeys the laws of geometrical optics. Typically but not exclusively, the gap width varies in the range 5 to 1000 micrometers.

Design of the Optical Elements

Most generally, the optical elements represent 3D regions of a transparent optical material with a relatively high index of refraction and having an arbitrary boundary (surface) with space. Any 3D surface can be closely approximated by a set of planar facets of an arbitrary area and hence, most generally, optical elements represent facetted polyhedra. In this context, the front surface 102, the peripheral surface 108 and the back surface 103 represent sets of planar facets. For the further discussion we introduce the term “exit-wall” defined as an arbitrary non-empty subset of facets lying on the peripheral surface 108 or on the back surface 103 since normally rays exit the optical element through these two surface elements.

Central to the invention is the design of the optical elements which are stated to possess the following specific properties:
a) The front surface 102 of each optical element 100 may be exposed to a diffuse light flux in the range

$$( - \frac{π}{2} , + \frac{π}{2} )$$

with respect to the axis 106.
b) The dominant fraction of the intensity of the diffuse light flux entering an optical element 100 through its front surface 102 upon exit from the optical element 100 is projected onto a limited area (called “diffuse element image”) lying in the focal plane 218 of the optical element.

Thus, we initially demonstrate the existence of optical elements with the above properties and disclose their design. To this end we consider an optical element 100 in the form of a two-dimensional pyramid (cone) made of an optical material with a refractive index n₁>1 (say, n₁=1.5) as illustrated in FIG. 2a. For specificity, it is also assumed that the pyramid is immersed in air 211, i.e. n₂=1. We also denote by θ_{c}=a sin(n₂/n₁) the critical angle for total internal reflection under these conditions. The z-axis of the reference coordinate system is assumed to be parallel to the axis 106 unless specified otherwise. For clarity of the presentation we initially assume that the angular dependence of the reflection coefficient for rays exiting the pyramid is a step function with values 0 and 1 where the transition from 0 to 1 takes place exactly at the critical angle of total internal reflection θ_{c}. This assumption, although approximate, is not very crude for moderate ratios n₂/n₁ and provides a fair first order approximation of ray refraction/reflection at such optical interfaces. Thus, a realistic reflection coefficient (say, glass/air interface) is closely approximated by a two-value function (0.04 and 1 respectively) with a steep transition between these two values around the critical angle of internal reflection.

Under the above conditions we consider the propagation of an arbitrary ray 200 entering an optical element 100 through its front surface 102 until the moment its refracted offspring 209 exits the optical element at point 205 and is supposedly projected onto the focal plane 218 as illustrated in FIG. 2a. We are interested in the largest lateral spread of the rays exiting the optical element. To this end we consider rays incident onto the front surface 102 from right to left (negative x-direction) in FIG. 2a and whose refracted rays 204 are incident onto the left exit-wall 212 only since we are looking for the smallest incidence angle with the exit-walls. Specifically, ray 200 enters the optical element 100 through its front surface 102 at an arbitrary point 201 and under an arbitrary angle 202 with respect to the axis 106, the latter is also assumed to be perpendicular to the front surface 102. The reflected fraction at point 201, if any, is disregarded since we are only interested in the fate of the rays entering the optical element. Under these conditions ray 200 experiences normal refraction and enters the optical element at point 201. The refracted ray 204 propagates through the optical element until it collides with the exit-wall 212 at point 205 under an angle 206 with respect to the normal 207 to the exit-wall 212. At this point we need to consider separately the cases where the angle of incidence 206 is smaller or larger than the critical angle θ_{c} for total internal reflection. We first consider the first case, i.e. where rays upon entry into the optical element 100 through its the front surface 102 exit immediately the cone at the very first collision with the exit-wall 212. For clarity we call such rays extrinsic. Specifically, ray 204 undergoes normal refraction at point 205 and exits the optical element at an angle 208 with respect to the normal 207 to the exit-wall 212. The magnitude of the internally reflected component in this event is zero in view of the assumptions above about the reflection coefficient being zero for incidence angles smaller than the critical angle θ_{c}. For the further discussion we need to erect certain mathematical relations for which reason we provide a parallel mathematical notation for some geometrical quantities in FIG. 2a as follows. We denote the incidence angle 202 upon entry as θᵢ, the incidence angle 206 prior to exit as γᵢ, the refraction angle 208 upon exit as γᵣ. What we are specifically interested is the minimum value of the γᵣ, since it is related to the maximum lateral spread of the refracted rays upon exit from the optical element. The sign of γᵢ is positive for clockwise rotation. We note that γᵢ is a decreasing function of θᵢ (since n₁>n₂) and therefore γᵢ attains its minimal value at θᵢ=π/2. Evidently, the same is true for γᵣ by virtue of Snell's law:

n₁·sin(γᵢ)=n₂·sin(γᵣ) (1)

Thus, assuming that θᵢ=π/2 from FIG. 2a it follows that the minimum value of γᵢ is given by:

γᵢ=π/2−θ_{c}−α/2 (2a)

From simple geometrical considerations in FIG. 2a it follows that a sufficient condition for the refracted ray 209 to have a negative component is:

0<π/2−θ_{c}−α/2+a sin[sin(α/2)n₂/n₁] (2b)

In eq. (2b), however, is always satisfied and attains the equality sign at α=π, meaning that all extrinsic rays upon exit from the pyramid have a negative component.

Combining eqns. (1) and (2a) results in the following equation for the minimum angle of refraction γᵣ:

γᵣ=a sin[cos(θ_{c}+α/2)·n₁/n₂] (3a)

We further denote by ψₑₓₜᵣ the angle 213 between the exiting ray 209 and vector 203, the latter being parallel to the normal vector 106 but having an opposite direction. From FIG. 2a it follows:

ψₑₓₜᵣ=π/2−γᵣ−α/2=π/2−a sin[cos(θ_{c}+α/2)·n₁/n₂]−α/2 (3b)

Here again, ψₑₓₜᵣ is always smaller than π/2 for α<π and becomes equal to π/2 when inequality (2b) assumes the equality sign. Since γᵣ denotes the minimum possible value of the refraction angle, ψₑₓₜᵣ denotes accordingly the maximum possible angle of the refracted extrinsic rays with respect to the vertical axis (vector 203) and, hence, they all are projected onto a limited area in the focal plane for any given value of α<π.
Further, the assumption γᵢ<θ_{c} along with eq. (2a) yields:

π/2−2θ_{c}<α/2 (4a)

Inequality (4a) represents a necessary condition in 2D for the existence of extrinsic rays. We introduce an angle β which has the meaning of the minimum incidence angle for which intrinsic rays exist:

β=a sin[cos(θ_{c}+α/2)·n₁/n₂] (4b)

Thus, the range of incidence angles θᵢ with respect to the normal 106 in which extrinsic rays may exist is given by:

β≤θᵢ≤π/2 (4c)

Hence, extrinsic rays are confined to the glancing incidence range of the light flux.

We now consider the case where γᵢ>θ_{c} meaning that the very first collision with an exit-wall represents total internal reflection. For clarity, such rays are called intrinsic. Thus, according to the definition such rays initially experience at least one or more total internal reflection events with the exit-walls before they attain an incidence angle smaller than θ_{c} and exit the optical element through refraction as illustrated in FIG. 2b. Specifically, ray 200 enters the optical element 100 through the front surface 102 at an arbitrary point 201 and under an arbitrary angle 202 with respect to the normal vector 106 to the front surface 102. Again, the reflected fraction, if any, at point 201 is disregarded since we are only interested in the fate of the intensity entering the optical element. Subsequently, the incident ray undergoes normal refraction upon entry at point 201 and continues propagation through the optical element as a refracted ray 204. Without loss of generality the ray's first two collisions with the exit-walls 212 at points 214 and 215 are assumed to be under total internal reflection. The important detail to note here is that the difference in the angle of incidence between two successive collisions with the exit-walls is exactly equal to α. This effect is commonly known as the escape-cone effect which refers to the back reflection of rays propagating inside a conical mirror through reflections off the cone walls. More specifically, such propagation results in a continuous decrease of the magnitude of the vertical component of the ray until it eventually reverses direction and the ray gets ejected from the cone. Thus, denoting the angle of incidence at point 214 by γᵢ then the angle of incidence at point 215 is exactly γᵢ-α, while the angle of incidence 206 at point 205 is exactly equal to γᵢ-2α. Consequently, the incidence angle γᵢ of any intrinsic ray eventually falls below the critical angle of internal reflection θ_{c} at which point it undergoes normal refraction and exits the optical element. To put it in another way, a 2D cone with an apex angle α exhibits a bandgap whose width is equal to (θ_{c}+a sin(sin(α/2)n₂/n₁)) and which bandgap “forbids” the propagation of rays along the negative z-direction with a magnitude of the z-component smaller than |−sin(θ_{c}+α/2)| since such rays get immediately refracted (expelled from the cone). Finally, the most important conclusion from this derivation is that all intrinsic rays that exit the optical element have incidence angles γᵢ lying strictly in the range (θ_{c}−α, θ_{c}) with respect to the normal 207 independently of their original direction upon entry into the cone, i.e.

θ_{c}−α<γᵢ<θ_{c} (5a)

Clearly, for the bandgap to be effective it is required that a be smaller than the width of the bandgap:

α<θ_{c}+a sin[sin(α/2)n₂/n₁] (5b)

which is an important condition, guaranteeing that all intrinsic rays will be refracted with a negative z-component of the refracted ray as will be shown shortly.
Further, a necessary and sufficient condition for a collision with the exit-wall to be intrinsic is the condition:

θ_{c}<γᵢ (6)

which together with eq. (2a) yields:

α/2<π/2−2θ_{c} (7)

In view of ineq. (4a) it follows that all rays that enter a pyramidal optical element through its front surface such that the pyramid's apex angle satisfies inequality (7), are intrinsic irrespective of their initial angle of incidence 202. Intrinsic rays always exist while extrinsic rays exist provided ineq. (4a) is obeyed. Further, ineq. (5a) indicates that the minimum incidence angle for intrinsic rays prior to exit from the optical element is θ_{c}−α. Subsequently, from Snell's law it follows that the minimum possible refraction angle γᵣ is given by:

γᵣ=a sin[sin(θ_{c}−α)·n₁/n₂] (8a)

Analogously to the extrinsic case (see FIG. 2b), ψᵢₙₜᵣ in the intrinsic case is given by:

ψᵢₙₜᵣ=π/2−γᵣ−α/2=π/2−a sin[sin(θ_{c}−α)·n₁/n₂]−α/2 (8b)

Equation (8b) defines the largest possible angle ψᵢₙₜᵣ between refracted intrinsic rays and the vertical axis (vector 203). Hence, all intrinsic rays upon exit from the optical element are angularly confined to the range (−ψᵢₙₜᵣ, +ψᵢₙₜᵣ) irrespective of their initial angle on incidence 202. Further, assuming the equality sign in ineq. (5b) eq. (8b) yields ψᵢₙₜᵣ=π/2 which illustrates the importance of ineq. (5b) namely if it is obeyed all intrinsic rays are refracted with a negative component and hence they all are projected onto a limited area in the focal plane.

Finally, a minor fraction of non-refracted rays would end up at the apex where the angle of incidence and consequently the angle of refraction are not strictly defined. Irrespective of this, however, such rays upon refraction are delivered in the focal plane due to its intimate proximity. Thus, we demonstrated that both extrinsic and intrinsic rays, having together or individually an initial angular divergence (−π/2,π/2) are projected onto a limited area in the focal plane provided ineq. (5b) holds. Since all rays, in view of the assumption about the reflection coefficient at the n₁/n₂ interface made above, carry forward their original intensity it follows that all initial intensity that enters the cone is delivered onto the focal plane 218 (excluding propagation losses).

As an illustration, assuming that α=10° equation (8b) yields ψᵢₙₜᵣ=32.77°. Noteworthy, the thus confined flux (now propagating in the low refractive medium, say, air) is readily fed into an optical waveguide, (say, made of glass or similar) where the above angular range is further confined to the range (−21.15°, +21.15°). Thus, suitable optical waveguides can be used for transporting further the light flux at longer distances. As a further illustration of the above results Table 1 presents data for a number of combinations of refractive indices and apex angles according to the above analysis. Noteworthy, lines 3 through to 6 and line 11 represent cases of intrinsic rays only, i.e. extrinsic rays do not exist in these cases since ineq. (4a) is disobeyed. As also seen, relatively large critical angles result in a relatively small divergence. For this reason, relatively large critical angles θ_{c} such as at interfaces between water/air, PMMA/air, etc represent preferred embodiments of the current invention.

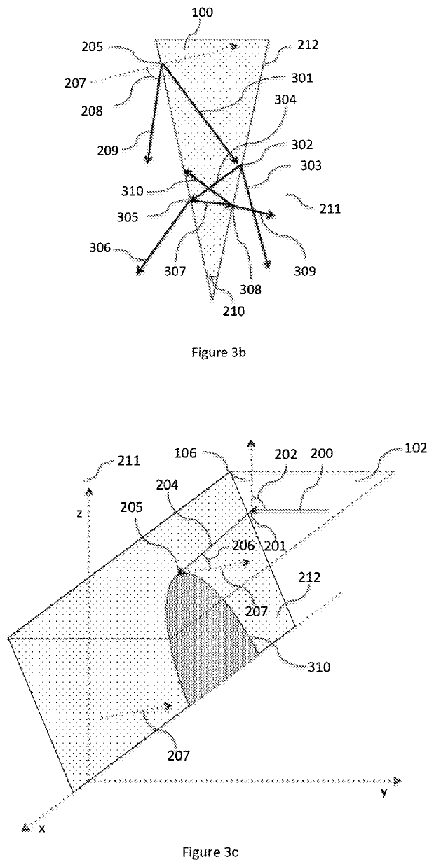

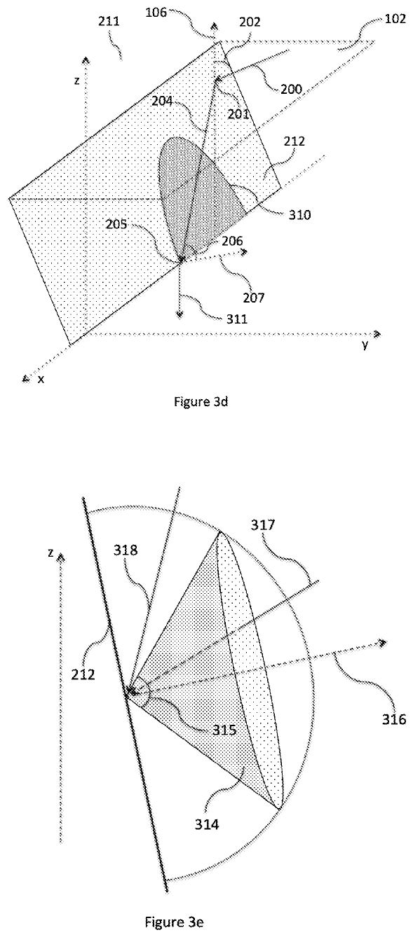

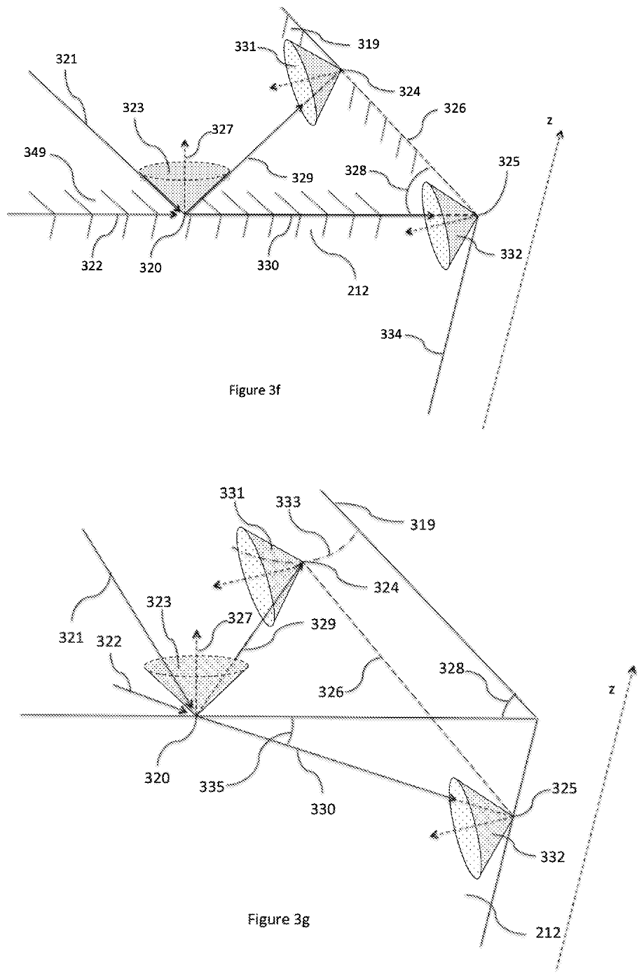

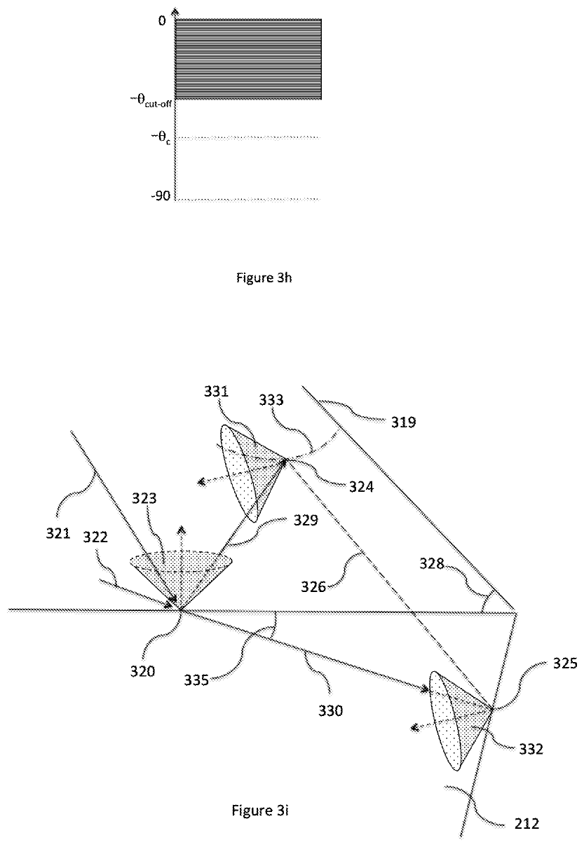

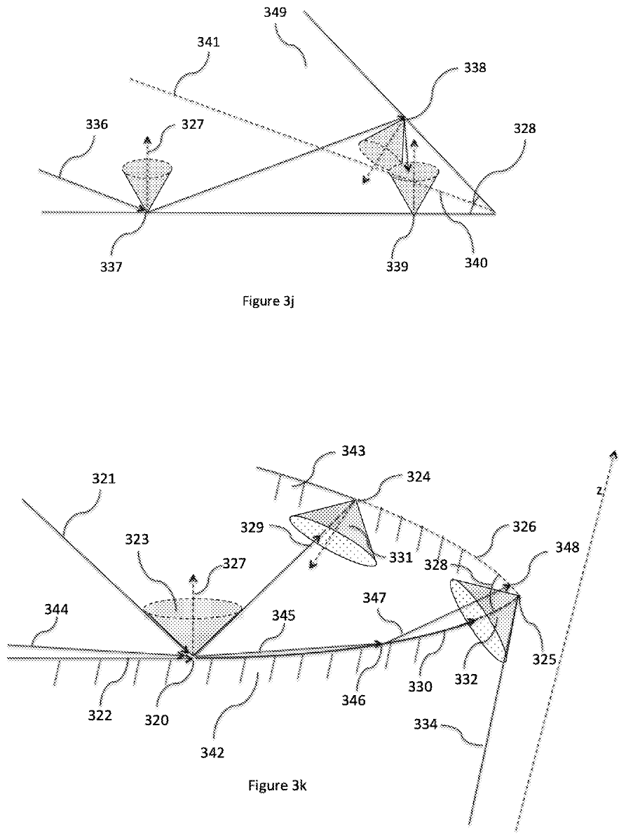

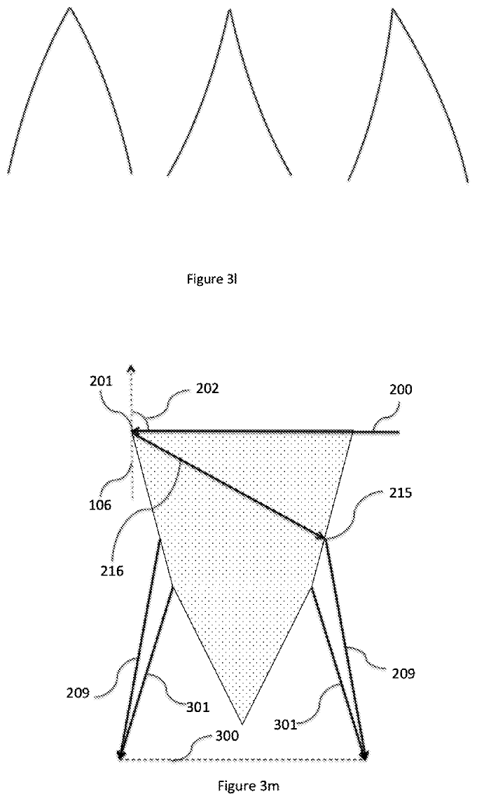

Further, it is clear that rays may leave the optical element at the earliest in the closest vicinity of the front surface through either exit-wall. Consequently, FIG. 3a illustrates graphically the above findings and more specifically, the fact that a diffuse light flux, incident onto the front surface 102 of the pyramidal optical element 100 upon exit from the optical element 100, is projected onto a limited area in the focal plane 218.

Graphically expressed, the diffusely illuminated front surface 102 is fully imaged onto the limited area 300 (diffuse element image) in the focal plane 218 bounded by the limiting rays 209 where the latter are defined by the larger value of eqns. (3b) and (8b).

We now drop the requirement for the reflection coefficient at the glass/air interface being a step binary function with values 0 and 1. We do this in two steps. Initially, we drop the requirement for the reflection coefficient being a step function only but retain the limiting values of 0 and 1. Thus, we assume that the rise of the reflection coefficient from 0 to 1 around the critical angle takes place over a small angular range 5 which is a very realistic assumption. It is easily seen that the existence of δ only offsets the incidence angle at which the refracted rays are fully transmitted, i.e. the angle at which the reflection coefficient drops to zero. Consequently, eq. (5a) now reads:

θ_{c}−α−δ<γᵢ<θ_{c} (9)

Subsequently, eqns. (8a,b) read:

γᵣ=a sin[sin(θ_{c}−α−δ)·n₁/n₂] (10a)

ψᵢₙₜᵣ=π/2−γᵣ−α/2=π/2−a sin[sin(θ_{c}−α−δ)·n₁/n₂]−α/2 (10b)

The effect on eqns. (3a) and (3b) is similar which we omit for brevity.
Clearly, the term δ in eqns. (10a,b) results in a corresponding (small) decrease of γᵣ and hence in a corresponding increase of the lateral spread of the refracted light flux. We finally assume that in addition to the existence of an angular range δ the reflection coefficient adopts the values of 0.04 and 1 below and above the angular range δ respectively, which as noted above is a very realistic approximation for the glass/air interface. Noting that total internal reflection to a first order of approximation is a lossless event one readily concludes that rays 204, 216 and 217 in FIG. 2b have equal intensities and hence as a result of the simultaneous reflection/refraction event at point 205 the refracted ray 209 retains 96% of the initial ray intensity while the internally reflected component retains 4% of the initial intensity only. The immediate result from this observation is that 96% of the initial flux intensity entering the optical element 100 through its front surface 102 is projected onto the diffuse element image 300 (excluding propagation losses). This concludes the proof that in a realistic situation the dominant portion of a diffuse light flux entering a 2D pyramidal optical element 100 through its front surface 102 upon exit from the optical element 100 is projected onto the diffuse element image 300, the latter having a limited area.

For completeness of the discussion we now consider the propagation of the internally reflected ray 301 generated at point 205 as illustrated in FIG. 3b which exemplifies schematically the evolution of the next three collisions of the reflected ray 301 with the exit-walls 212 where each successive collision results in a split through simultaneous reflection/refraction events. Specifically, the reflected ray 301 collides successively with the exit-walls 212 at points 302, 305 and 308 where it undergoes simultaneous reflection/refraction events such that each successively refracted ray carries away 96% of the momentary intensity while the internally reflected component retains the rest. In other words, the intensities of both the successively reflected (301, 304, 307 and 310) and refracted (303, 306 and 309) rays decay exponentially at each successive collision. The other conclusion following from the fact that the angle of incidence at each successive collision decreases by a is that the lateral spread of the (higher generations) refracted rays increases with each successive collision. All this results in a blur of an exponentially decreasing intensity of the outer edge of the diffuse element image 300. Finally and more importantly, the angle of incidence with successive collisions for rays remaining within the cone decreases continually and eventually reverses its sign which subsequently results in a reverse (upward) component of the reflected ray 310. Such reflected rays or rather their reflected/refracted off-springs propagate unhindered upwards and they all get eventually discharged back into the ambient. Clearly, this rejection mechanism is nothing else but the familiar cone effect restricted to partially reflected rays only, for which reason it is called secondary escape-cone effect.

We now consider the validity of the above analysis in 3D. We first consider the extrinsic case. FIG. 3c illustrates in 3D a section of an optical element 100 where the front surface 102 meets the exit-wall 212. Ray 200 is incident under an angle 202 equal to π/2 with respect to the normal 106 of the front surface at point 201 such that the plane of incidence is perpendicular to the exit-wall 212, i.e. the ray 200 lies in the plane of FIG. 2a and which plane we call frontal. We now rotate vector 200 about the normal 106 in the range (−π/2, π/2) as a result of which the intersection point 205 between the refracted ray 204 and the exit-wall 212 follows a parabolic (or elliptic) trajectory 310. From simple geometrical considerations it follows that the distance between the point of incidence 201 and the intersection point 205 (between the refracted ray 204 and the exit-wall 212) is shortest in the frontal plane of incidence and hence angle 206 is still the smallest in the frontal plane. Therefore, ineq. (4a) is still sufficient for the existence of extrinsic rays in 3D. The angle α/2 now defines the z-component of the normal 207 to the exit-wall 212 which component is equal to sin(α/2). Eq. (3b) still holds in 3D but only in the frontal plane. This necessitates evaluation of the spread of extrinsic rays along the x-axis. To this end, FIG. 3d shows the trajectory of a presumed extrinsic ray 200 incident in the surface plane 102 and having an arbitrary azimuthal coordinate defined by ϕ in the interval (−π/2,π/2) with respect to the frontal plane. Consequently, its refraction 204 will hit the exit-wall 212 at point 205 lying on the parabola 310 and will be further refracted by the exit-wall 212 to exit the optical element as ray 311. We are interested in the z-component of ray 311. To this end we denote the normal 207 as vector m=(0, cos(α/2), sin(α/2)) in the coordinate system in FIG. 3d, i.e. the x-axis lies in the plane of the exit-wall 212. We also denote by r the unit vector along the direction of ray 204 as r=(sin(φ)sin(θ_{c}), −cos(φ)sin(θ_{c}), −cos(θ_{c})). Subsequently, the incidence angle γᵢ of ray 204 at point 205 is

cos(γᵢ)=−r·m=cos(α/2)cos(φ)sin(θ_{c})+cos(θ_{c})sin(α/2) (11a)

The refraction angle then is

γᵣ=a sin(sin(γᵢ)n₁/n₂) (11b)

The unit vector t along the refracted ray 311 is given by

t=−m·cos(γᵣ)+(m×r)×m·sin(γᵣ)/sin(γᵢ) (11c)

and consequently the z-component of vector t is:

$${t}_{z} ( φ ) = - sin \frac{α}{2} cos ( {γ}_{r} ) + [ sin \frac{α}{2} cos \frac{α}{2} cos ( φ ) sin ( {θ}_{c} ) - {cos}^{2} \frac{α}{2} cos ( {θ}_{c} ) ] \frac{sin ( {γ}_{r} )}{sin ( {γ}_{i} )} \qquad ( 11 d )$$

The component t_{z}(φ) attains its minimum magnitude and, hence, ray 311 attains its maximum lateral component at <φ=0 and at which point eq. (lid) reduces to:

t_{z}(0)=−cos(ψₑₓₜᵣ) (11e)

where ψₑₓₜᵣ is given by eq. (3 b).
In other words, the lateral component of ray 311 is maximum when ray 204 lies exactly in the frontal plane. Therefore, eq. (3b) still describes the maximum divergence of extrinsic rays in 3D.

We now consider the intrinsic case in 3D. Referring to FIG. 3c it is noted that ineq. (7) was derived in the frontal plane. As shown above, the angle of incidence in this plane is still the smallest in 3D as ray 200 is rotated about the normal 106 and, hence, if ray 200 in FIG. 3c is intrinsic then all other rays are intrinsic too. Hence, ineq. (7) still guarantees that all rays are intrinsic irrespective of the angle of incidence 202. Eqns. (8a) and (8b), however, are no longer valid in 3D and, therefore, further analysts is needed to demonstrate the angular confinement of intrinsic rays as follows. FIG. 3e illustrates the way an intrinsic ray propagating inside the optical element “sees” an exit-wall 212. Specifically, FIG. 3e illustrates a cone 314 (also called unit refraction cone or simply refraction cone) whose aperture 315 is equal to 2θ_{c} and whose axis 316 is perpendicular to the exit-wall 212. For clarity, the top section of the refraction cone is truncated to illustrate its three-dimensionality. The axis of the refraction cone is always normal to the plane refracting the ray and the cone apex always coincides with the point of incidence. Thus, rays whose directions are contained within the angular range of the refraction cone (cone aperture), say ray 317, have an incidence angle smaller than the critical angle θ_{c} and hence get refracted by the exit-wall 212. Conversely, rays, say 318, whose unit vectors fall outside the angular range of the refraction cone 314 continue their propagation through total internal reflection. Therefore, the exit of intrinsic rays from the optical element in 3D generally represents a probabilistic event unlike the 2D case where the existence of a bandgap guarantees that all intrinsic rays with a sufficiently small magnitude of the z-component are expelled from the cone. It is then clear that there is always a finite probability that a ray never gets refracted by the exit-walls. In other words, such a ray gradually loses its z-component (in absolute value) in successive reflections until its sign is reversed and eventually gets ejected back into the ambient without losing any intensity in the process. This is a manifestation of the primary escape-cone effect through total internal reflection and needs to be accounted for in any optical device operating through total internal reflection. The term primary is used to denote the fact that the ray is rejected without loss of intensity.

We now demonstrate that optical elements in 3D can be designed such that:
a) the above escape-cone effect is suppressed for all intrinsic rays
b) all intrinsic rays exit the optical elements and are projected onto a limited area in the focal plane of the optical elements
   FIG. 3f shows an arbitrary cross-section 349 of the edge 334 formed between two neighboring planar exit-walls 212 and 319 and which cross-section is perpendicular to the edge 334. We further assume that exit-walls 212 and 319 are in direct visibility with each other, i.e. there is no other facet between them and hence rays can propagate unhindered between then. For clarity of the discussion it is assumed that the z-axis is parallel to edge 334. We consider the trajectories of all rays with non-positive z-components propagating inside the optical element and incident onto exit-wall 212 at an arbitrary point 320, the latter lying on the intersection line with the cross-section 349, as well as having a lateral component directed towards edge 334. We consider the rays incident outside cone 323 only since those which enter the latter are immediately refracted. Initially, we consider rays 321 and 322 lying in the plane of the cross-section 349, i.e their z-components are zeroes. Ray 321 is assumed tangential to the refraction cone 323 whereas ray 322 lies in the plane of exit-wall 212. In other words, these two limiting rays define the range of all rays outside the refraction cone 323, initially lying in the cross-section 349 in FIG. 3f and that undergo total internal reflection at point 320. Note that axis 327 of cone 323 also lies in the plane defined by rays 321 and 322, i.e. in the cross-section 349. Ray 321 upon reflection at point 320 continues as ray 329 which in turn collides with exit-wall 319 at point 324. Ray 322, lying in the reflecting plane 212, continues after “reflection” at point 320 without changing direction as ray 330 until it collides with edge 334 at point 325. Clearly, all other intermediate reflected rays lying in the plane of the cross-section 349 and having intermediate directions between rays 329 and 330 collide with exit-wall 319 between points 324 and 325 and hence, the dashed line 326 represents the locus of their intersections with the exit-wall 319. All rays lying in the plane of the cross-section 349 and contained within the angular range between rays 321 and 322 we denote as ray sector and analogously the corresponding sector of the reflected rays we denote as ray sector image. We further assume that angle 328 is chosen such that both reflected rays 329 and 330 enter their respective refractive cones 331 and 332 from the inside. We also refer to angle 328 as internal to reflect the fact that it is internal with respect to the bulk of the optical element, i.e. it encloses part of the optical element. Denoting the internal angle 328 between the exit-walls 212 and 319 by (it is readily seen that a suitable choice for angle 328 is given by:

π/2−θ_{c}<ζ<2θ_{c} (12)

In other words, for edges with internal angles C, lying outside the interval defined by inequalities (12) the reflected rays 329 and 330 cannot simultaneously fall within their refractive cones 331 and 332 respectively. Further, it is clear that if both rays 329 and 330 enter their refraction cones 331 and 332 respectively, so do all other rays in the ray sector image. We now start rotating anti-clockwise the plane defined by rays 321 and 322 about the axis 327 of refraction cone 323. Consequently, the entry points of rays 329 and 330 into their respective refraction cones 331 and 332 will start drifting towards the edges of the latter. At the same time, point 324 will follow a parabolic (elliptic) trajectory 333 defined by the intersection of the conical surface of cone 323 with the exit-wall 319, while point 325 will strictly travel down the edge 334 as illustrated in FIG. 3g. At a particular angle of rotation 335 one or both of the reflected rays 329 and 330 will become tangential to their respective refraction cones as illustrated in FIG. 3g where we have chosen the case where only ray 329 becomes tangential to its refraction cone 331 while ray 330 still remains internal with respect to its own refractive cone 332. We denote the ray sector for which this happens as the cut-off ray sector. Clearly, all rays from the cut-off ray sector image as well as the rays of all previous ray sectors images are refracted since they all enter their respective refraction cones on the inside by virtue of the above construction. Noteworthy, ray 321 has the smallest z-component (in absolute value) within each ray sector by virtue of the smaller angle formed with the axis of rotation 327. We thus denote the z-component of ray 321 in the cut-off ray sector by −sin(θ_{cut-off}) since this guarantees that all rays with a smaller in magnitude z-component and entering the edge according to the above construction are refracted. Point 320 was chosen arbitrarily, likewise the cross-section 349 in FIG. 3f, and hence the above findings hold for any point on exit-wall 212. The same is exactly true for rays initially incident onto exit-wall 319 due to the symmetry of the construction. Thus, we have demonstrated the existence of a forbidden zone (bandgap) such that all rays that enter an edge between the two exit-walls satisfying relations (12) and having a magnitude of the z-component (measured with respect to the edge 334) smaller than |−sin(θ_{cut-off}) are refracted. The bandgap thus demonstrated is a property of the edge itself for a given materials combination (n₁,n₂) and hence optical elements with at least one edge of non-zero bandgap will have the same property as the edge itself, i.e. “forbid” propagation of rays with a magnitude of the z-component (relative to the edge) smaller than the bandgap width since they get refracted as soon as they enter the edge. We just keep in mind that the bandgap is not aligned with the original z-axis and that it is always associated with an edge between two exit-walls. FIG. 3h shows an illustration of this bandgap. Specifically, when intrinsic rays enter the optical element they possess a magnitude of the z-component sin(θ) where θ lies between θ_{c} and 90°. As the magnitude of the z-component of a ray in successive reflections continually decreases (in a presumably conically shaped optical element) the ray eventually enters an edge with a nonzero bandgap and concludes an angle θ relative to the edge which is smaller than the lower edge θ_{cut-off}, and hence, the ray gets refracted.

Eventually, all rays get refracted in an identical manner with the exception of those ending up at the apex which is discussed below. Since the incidence angle upon refraction is limited by the lower bandgap edge then analogously to the 2D case all refracted rays are projected onto a limited area in the focal plane. Specifically, the minimum angle of incidence γᵢ is:

γᵢ=θ_{cut-off}−α/2 (13a)

where α/2 corresponds to the slope of exit-wall through which the rays exit and hence from Snell's law it follows

ψᵢₙₜᵣ=π/2−γᵣ−α/2=π/2−a sin[sin(θ_{cut-off}−α/2)·n₁/n₂]−α/2 (13b)

Further, the above geometrical construction can be optimized by finding an optimal edge angle (such that both rays 329 and 330 upon the above rotation become simultaneously tangential to their respective refractive cones and hence the width of the bandgap is largest as illustrated in FIG. 3i. From simple geometrical considerations it follows that this is achieved for an angle 328 given by:

ζ=a cos[1−sin(θ_{c})] (14)

We further denote the angle of rotation 335 by co at the moment rays 329 and 330 become tangential to their respective refraction cones. Given the angle (one readily calculates the angle of rotation co from the fact that ray 330 becomes tangential to cone 332 at the intersection between cone 332 and plane 212. Hence co is given by:

ω=a sin[sin(θ_{c})\sqrt{1−cot²(θ_{c})cot²(ζ)}] (15)

Finally, having calculated the rotation angle ω it is straightforward to calculate the z-component of ray 321 from the corresponding to co ray sector and which component corresponds to the edge of the bandgap θ_{cut-off}

θ_{cut-off}=a sin[sin(θ_{c})sin(ω)] (16)

As an illustration, assuming θ_{c}=48.61° eqns. (14,15,16) yield ζ=75.5?>⁰, ω=46.93° and θ_{cut-off}=33.23° respectively. Noteworthy, eq. (15) may be used for values of (smaller than that given by eq. (14) but still larger than (π/2−θ_{c}) since ray 330 exits its refractive cone before ray 329 exits its cone and hence eq. (15) holds in such cases. As expected, zero rotation angle ω=0 is achieved for ζ=π/2−θ_{c}. For edge angles 328 greater than the value given by eq. (14) the following equation is used instead of eq. (15):

$$ω = acos [ cot ( {θ}_{c} ) \frac{1 - cos ( ζ )}{sin ( ζ )} ] \qquad ( 17 )$$

since in such cases ray 329 leaves its refractive cone 331 first. Eq. (16), though, still holds. It is a trivial trigonometric exercise to prove that the right hand sides of eqns. (15) and (17) are identical functions of θ_{c} for (given by eq. (14), that is, they both yield the same rotation angle ω for ζ=a cos[1−sin(θ_{c})] but other than that they should be used in their respective angular ranges for ζ. Eq. (17) may be used for values of ζ up to 2 θ_{c} for which value it yields ω=0 as expected. It is also noted that the bandgap given by eq. (16) is somewhat conservative. Thus, the bandwidth θ_{cut-off} may further be optimized by designing the angle ζ in such a way that ray 330 exits cone 332 before ray 329 exits cone 331 such that the z-component of ray 329 at the moment of exit from cone 331 is equal to the z-component of ray 330 at the moment it exited cone 332 earlier. This, however, is beyond the scope of the current presentation.

As an illustration of the above analysis we consider the case θ_{c}=30° (say, n₁=2 and n₂=1) and hence ζ=60°. Consequently, we consider a concentrator consisting of optical elements representing triangular pyramids with an equilateral base (further details given below). From eqns. (15 and 16), however, it follows that the width of the bandgaps of all exit-wall edges is diminishing (assuming that the edge angles 318 between all three pairs of exit-walls are approximately equal to 60°). Consequently, intrinsic rays will be refracted probabilistically only while the rest will be rejected eventually through the primary escape-cone effect. Indeed, ray tracing calculations of a concentrator with the above optical elements' geometry result in a rejection coefficient of 38.04% at a concentration of 100 suns (defined as the ratio between the input and output areas). This large rejection coefficient is solely due to the unchecked primary escape-cone effect. Such concentrators are called “bright” to illustrate the fact that they reflect a substantial fraction of the light intensity back to the source. Without changing the geometrical dimensions of the optical elements the same calculations for θ_{c}=48.6° (n₁=1,33 and n₂=1) result in a rejection coefficient of 0.0037% (being non-zero is actually due to secondary escape-cone mechanisms discussed below) since in this case the bandgap width according to eqns. (15,16) for all three edges (ζ≈60°) is θ_{cut-off}=28.98°, i.e. it is sufficiently large to totally suppress the escape-cone effect and guarantee orderly exit of all intrinsic rays. Such concentrators are called “dark” to illustrate the fact that they reflect only a small amount of the incident light intensity.

The above example, however, does not serve to indicate that optical elements forming a critical angle θ_{c}=30° with respect to the gap material cannot be designed to suppress to a large extent the primary escape-cone effect. Further, according to ineq. (12), edges with angles 318 smaller than π/2−θ_{c} do not exhibit non-zero bandgaps. Specifically, rays with a considerable lateral component along the exit-wall 212 are not refracted (do not fall within the refraction cone 332). Analogously, rays with a considerable lateral component along wall 319 have the same fate. On the other hand, such edges play the role of the escape-cone effect with respect to the lateral component of such rays. In other words, the latter will bounce off the two walls of the edge until they gain sufficient lateral component with respect to the bisector 341 of the edge angle (in addition to losing a vertical momentum in the process) and get consequently refracted through refractive cone 331 or its counterpart on wall 212 as illustrated in FIG. 3j. Hence, such edges act as bandgaps which expel intrinsic rays. This process is equivalent to the propagation of intrinsic rays in 2D. The situation here is mirrored, that is, it is the lateral component which loses magnitude with respect to the bisector 341 of the edge until the ray eventually enters a refraction cone. Rays, still having a significant vertical direction which prevents them from entering a refractive cone on either exit-wall, are eventually reflected back to the bulk of the optical element and undergo a similar process at the next edge. We refer to such bandgaps as horizontal to denote the fact that they relate to the lateral component of the ray. Likewise, we call the bandgaps described above as vertical to denote the fact that they refer to the z-component of the ray. Noteworthy about horizontal bandgaps, a ray may still get refracted even if the horizontal component changes direction with respect to the bisector 341. Thus, the width of horizontal bandgaps is equal to the full aperture 2θ_{c} of the unit refraction cone. The role of the apex angle α in the 2D case is now taken by the edge angle ζ. Therefore, horizontal bandgaps exist under the following conditions:

0<ζ<2θ_{c} (18a)

Comparing ineq. (18a) with ineq. (12) it is seen that ineq. (18a) represent the union of the two. Therefore, non-zero bandgaps (vertical or horizontal) may exist under ineq. (18a). It is further seen that if ineq. (12) are satisfied both vertical and horizontal bandgaps operate in concert.

Further, partial horizontal bandgaps (or partial bandgaps discussed in more detail shortly) may also exist for angles ζ larger than 2θ_{c} which explains partly the relatively high transmission coefficient of 62% in the example for θ_{c}=30° and ζ=2θ_{c} above and which coefficient translates into an efficiency in the range of evacuated solar thermal collectors. To further illustrate this we consider the case θ_{c}=20° and ζ=45°. Referring to FIG. 3j and considering for simplicity ray propagation in the plane of the cross-section 349 of edge 334 we assume that ray 336 is incident (with a large lateral component), say, at 80° with respect to the normal 327 at point 337. Consequently, the incidence angle at point 338 is 35° while at point 339 is −10° and the ray, hence, is refracted by the refractive cone 340 at point 339. Hence, partial horizontal bandgaps may also exist to some extent beyond the limit of 2θ_{c}. For this reason ineq. (18a) are extended as follows:

0<ζ<2.5θ_{c} (18b)

As a further illustration, ray tracing calculations of exactly the same concentrator geometry as in the example above but for θ_{c}=20°, i.e. ζ≈3θ_{c}, yield a transmission coefficient of about 18%, i.e. an efficiency comparable with that of common non-insulated solar thermal collectors. All this indicates that the extension made in ineq. (18b) is more than reasonable. Hence, so far we can conclude that an optical element according the present invention is such that it has at least one edge whose edge angle (satisfies ineq. (18b).

The derivation of the bandgaps above was done under the assumption that the edge 334 is geometrically sharp which is a mathematical idealization. In reality, edge 334 will naturally have a finite curvature. Hence, rays colliding with the curved section, particularly such under a glancing incidence, may not be refracted, thus resulting in the formation of an incomplete or partial bandgap. Therefore, strictly speaking, in reality all bandgaps are incomplete. Incomplete bandgaps, most generally, arise in situations where some facets lying on, say, exit-wall 212 do not form angles satisfying ineq. (18b) with some facets lying on exit-wall 319, where most generally exit-walls 212 and 319 represent curved surfaces and the latter are approximated by planar facets of arbitrary areas. The fact that bandgaps are incomplete does not mean that they are ineffective. Rays propagating through incomplete bandgaps simply follow the natural law where loss is proportional to propagation distance and hence the number of non-refracted rays decays exponentially with propagation distance (or number of reflections). In other words, the existence of a partial bandgap results in that the probability of a ray not being refracted decays exponentially with the number of collisions with the exit-walls.

Further, it is also clear that there exists a large number of extensions and variations to the construction in FIG. 3f which effectively amount to the definition of incomplete or even modified (enhanced) bandgaps. As an illustration of the latter case, FIG. 3k illustrates the cross-section of an edge formed between the intersection of two curved convex exit-walls 342 and 343 approximating the planar exit-walls 212 and 319 respectively in FIG. 3f. Without entering a detailed discussion it is clear that such a geometry would result in an enhanced width of the vertical bandgap since the axes of cones 331 and 332 are no longer parallel to each other but both form favorable angles with the reflected rays 329 and 330 respectively resulting in an increased bandgap width. Additional focusing effects may also occur. Example of the latter is ray 344 which is reflected at point 320, continues as ray 345 and reflected again at point 346 to continue as ray 347 and finally refracted at point 348. The refraction cone at point 348 is omitted to avoid clutter. The net result is an increase of the width of the vertical bandgap since this geometry increases the residence times of rays 329 and 330 in their respective refraction cones during the ω rotation. This enhancement, however, is at the expense of the efficiency of the horizontal bandgap since rays propagating towards edge 334 gain lateral momentum in a non-linear fashion (following from the curvature of the surface). A similar construction with concave exit-walls has its own advantages with respect to horizontal bandgaps at the expense of vertical bandgaps. In this context one can discern three basic edges types with curvilinear cross-sections as illustrated in FIG. 3l. Thus, the edge in FIG. 3l (left) illustrates the case discussed in relation to FIG. 3k, and as concluded it results in an enhancement of the vertical bandgap. The second edge type (middle) results in enhancement of the horizontal bandgap due to the under linear decrement of the angle between the two exit-walls towards the edge. The third (right) is of mixed type. Edges with curved exit-walls introduce a topological challenge in arranging optical elements tightly to each other. Combining optical elements with both convex and concave edges might partially alleviate this problem.

One can, cleary, construct a large number of variations to the constructions in FIG. 3l but they all follow the same principle of bandgap formation and do not represent in any way departure from the current invention. The common denominator between all of them is the existence of at least one partial bandgap, i.e. the existence of two subsets of facets on either exit-wall of an edge such that each facet from the first subset is in direct visibility with each facet from the second subset and which facets form angles with each other satisfying ineq. (18b). Curved exit-walls also fall under this definition since any curved surface can be represented by a set of facets of an arbitrary area. Optimal performance obviously is achieved by optimizing the overall area of such subsets of facets. Thus, we can state that a minimum requirement for this invention is the existence of at least one edge with a partial bandgap. Preferred embodiments make use of planar exit-walls.

Finally it should be noted that ineq. (18b) alone do not guarantee that most of the rays will be ejected through the exit-walls, while exit of a substantial fraction of rays through the bottom surface or apex is not always desirable. Thus, one needs to implement a mechanism which constantly reduces the magnitude of the vertical component of intrinsic rays so that the majority of rays are consequently expelled from the optical element through the exit-walls by partial and/or complete bandgaps. This is achieved by requiring that the area of the horizontal cross-section of an optical element generally decreases with increasing the distance from the front surface which is a further requirement for the optical elements in this invention. In other words, the shape of the optical elements is that of a general cone (decreasing lateral dimensions from top to bottom) and which shape would equally importantly prove useful in achieving light concentration as demonstrated shortly.

Finally, for the proof to be complete one needs to account for rays which end up at the bottom of the optical element without gaining sufficient lateral component to exit the latter. For optical elements with sufficiently sharp tips the refraction angle at such points is not defined. The important fact in this case is that such rays upon refraction are delivered in the focal plane irrespective of their angles of refraction. On the other hand, ineq. (12) provides a possibility to force all such rays exit the tip by designing the latter to represent an edge perpendicular to axis 106 and satisfying ineq. (12), preferably having an edge angle defined by eq. (14). It is clear that all rays having a substantial vertical component and entering such an edge will be refracted since bandgaps exist along both directions of the edge. This completes the proof in 3D that there exist optical elements for which all intrinsic rays irrespective of their initial angle of incidence onto the front surface are projected onto a limited area in the focal plane.

A final note on the choice of the apex angle α. It is trivial to prove that the maximum height measured from the apex at which intrinsic rays start to refract decreases with decreasing the apex angle α and thus the area of the diffuse element image 300 decreases accordingly. This fact can be used to additionally decrease the area of the diffuse element image 300 by altering the geometry of the optical elements as shown in 2D in FIG. 3m. Specifically, the slope of the exit-walls near the front surface is made larger than their slope near the apex. Ray 216 represents the limit where the incidence angle 202 of an intrinsic ray approaches π/2 and the point of incidence approaches the leftmost point on the front surface. Clearly, this geometry results in an overall reduced area of the diffuse element image 300 as compared to the case where the exit-walls have a constant slope equal to that at the lower section of the optical element. This also reduces the height of the optical elements as well as accelerates ray ejection due to an increased effective apex angle. The same approach is used for nesting optical elements as discussed below.

Finally and analogously to the 2D case, it is reiterated that all refracted rays (both intrinsic and extrinsic) carry forward the larger part of the initial intensity and hence in 3D the dominant fraction of the initial intensity is projected onto the focal plane.

A note on the front surface 102. It represents an interface between the low refractive index medium and the bulk of the optical element. Its main function is to convert the incident flux with a divergence (−π/2, π/2) down to (−θ_{c}, θ_{c}) with respect to axis 106. Its geometrical shape can be anything as long as this condition is satisfied. In preferred embodiments its shape is spherical or planar.

Design of a Diffuse Light Concentrator

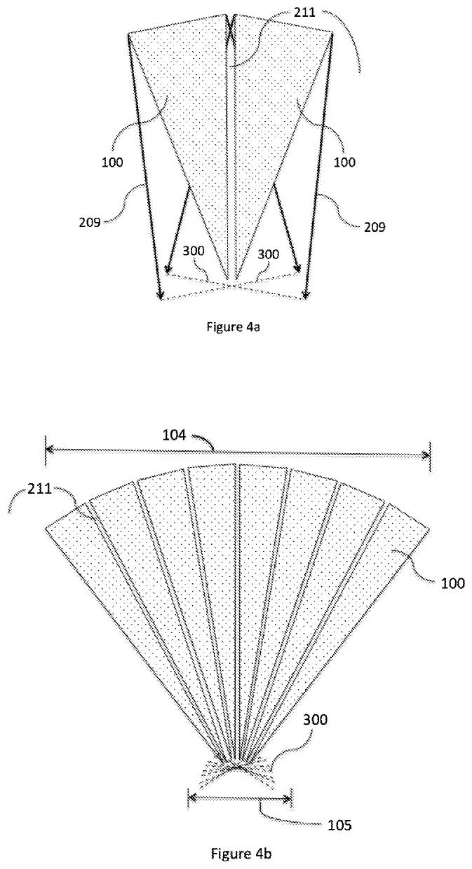

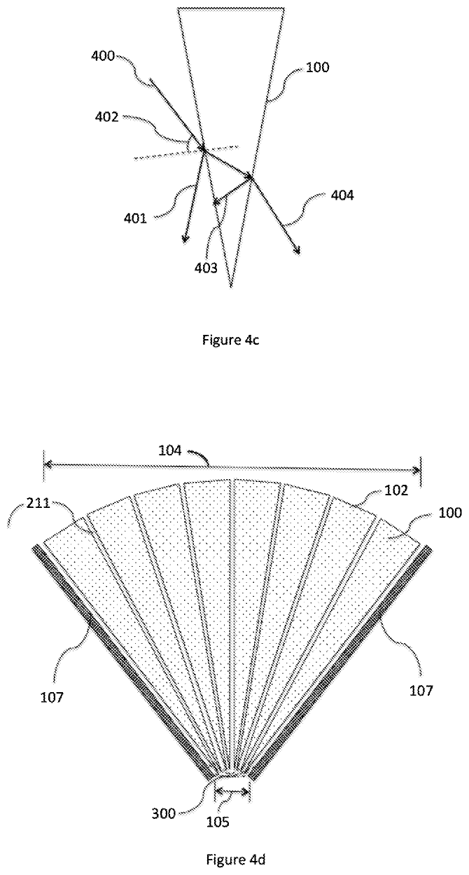

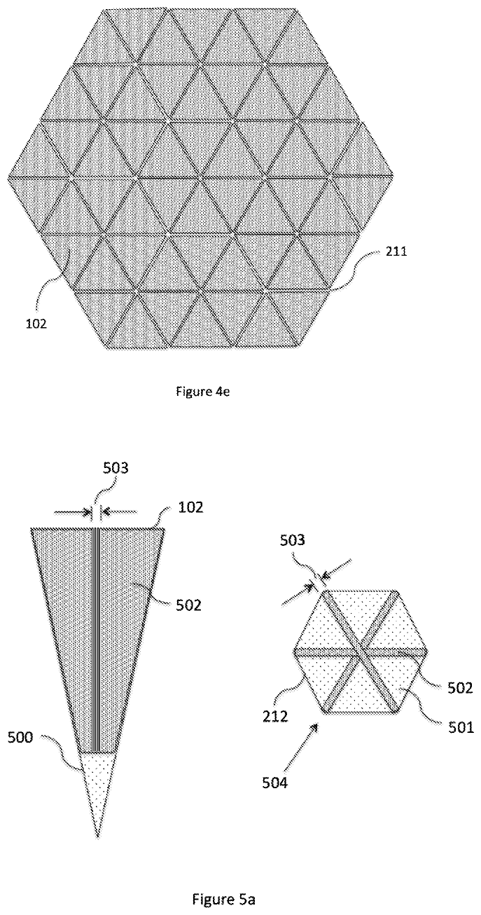

We are now in a position to construct a diffuse light concentrator using the optical elements above. For specificity, we assume that the optical elements represent triangular pyramids and continue the discussion in 2D where the pyramids are represented by 2D cones but the arguments equally hold in 3D according to the analysis above. FIG. 4a displays schematically the arrangement of two pyramidal optical elements 100 in such a way that their respective diffuse element images 300 overlap to a large extent. It illustrates graphically the possibility of arranging a number of optical elements tightly to each other but still separated by low refractive index gaps such that the larger parts of the individual diffuse element images 300 overlap resulting in a smaller exit aperture than the sum of all front surface areas along with the effective area of the gaps between them. In other words, FIG. 4a illustrates one of the mechanisms of light concentration in the present invention. The important detail here is the conical shape of the optical elements which makes it possible to place them closely to each other in such a way that their diffuse element images overlap to a great extent. We call such optical elements “concentrating” since their conical shape allows light concentration through overlap of diffuse element images. Most generally, such elements have a decreasing cross-section with increasing distance from from front surface. For the remainder of the presentation we consider such concentrating optical elements only but for brevity continue to refer to them as optical elements. Further, in analogy with FIG. 4a one readily constructs an array of optical elements arranged in a similar fashion to each other so that neighboring diffuse element images overlap to a great extent as illustrated in FIG. 4b. It is obvious that by virtue of the conical shape of the optical elements all diffuse element images 300 superimpose onto the diffuse source image 105, the area of which owing to this same superposition is typically smaller than that the diffuse source 104. Further, FIG. 4c shows the fate of a ray 400 that has just exited an optical element. Specifically, it gets partially reflected (ray 401) upon entry into the neighboring optical element, then further partially reflected (ray 403) and finally refracted (ray 404). It is clear that the lateral components of rays 401 and 403 are smaller than that of ray 400 (x-axis assumed positive to the right) resulting in a skew in the intensity of the optical image 300 towards its center. More important is the fact that this effect takes place at all interfaces resulting in collective focusing effects thus suppressing substantially the secondary escape-cone effect between optical elements discussed below. Thus, the interface density (number of optical elements in a concentrator) plays a significant role particularly in view of the fact that ray 404 carries forward the major fraction of intensity. Since, triangular pyramids have a high surface to volume ratio and provide high interface to volume density for which reason they represent a preferred embodiment of optical elements. Most generally, the number of interfaces between the optical elements is optimized by increasing the number of the latter. For practical reasons, however, it is desirable that the acceptance surface of the concentrator does not deviate substantially from planar and hence typically a diffuse light concentrator occupies a limited solid angle. Hence, increasing the number of the optical elements results in that an individual optical element in a concentrator occupies a correspondingly smaller solid angle, or in other words, the exit-walls have a correspondingly larger slope. The additional benefit of this is that both extrinsic and intrinsic rays have a correspondingly smaller element source image 300 (both in absolute and relative terms) which facilitates focusing. For these reasons, the diffuse light concentrator is said to consist of a multitude of optical elements.

Finally, in order to further confine the exit flux reflecting mirrors 107 are placed on the periphery of the concentrator as illustrated in FIG. 4d. These peripheral mirrors reflect all light flux that drifts sideways back into the core of the concentrator and physically restrict the diffuse source image (exit aperture) through its exit aperture 105 thus providing a further focusing mechanism in the current invention. Thus, FIG. 4d represents a schematic of a diffuse light concentrator. Revisiting FIG. 4c it is obvious that a substantial fraction of the intensity does drift sideways and hence the mirror structure is an essential element in the current invention in that it confines light intensity which which otherwise would have drifted laterally. In preferred embodiments the mirrors are separated from the optical elements by gaps comprising a low refractive index material although they may also be in intimate contact with the optical elements. In preferred embodiments the distance between the mirror input and exit apertures is approximately equal to the height of the optical elements. Extending the mirror structure beyond the back surfaces to increase concentration or above the front surfaces to increase acceptance area (incident flux) represent trivial extensions to the present invention and do not constitute departure from it. The use of external mirrors in proximity with the concentrator to redirect additional light onto the acceptance aperture of the concentrator also represents a trivial extension of the present invention and does not constitute departure from it. The concentration coefficient can be varied independently by both the gap width and the exit aperture defined by the peripheral mirror structure 107. The latter is typically achieved by varying the vertical position of the exit mirror aperture in which case the optical elements can be suitably truncated below the exit aperture. The gap width, as noted, should be large enough to guarantee validity of geometrical optics or in other words, they should be typically significantly larger than the largest wavelength under consideration. In preferred embodiments the gap width is as uniform as possible although it does not need to be uniform and represents a free design parameter typically used for adjusting the concentration coefficient amongst others since gaps do not contribute to light concentration and increasing their widths leads to a decrease in the concentration coefficient. The gap width is also used as a space obliterating parameter since in most cases not all exit-walls can be made parallel to each other in 3D. It is also clear from the above discussion that the acceptance angle of the concentrator is not related to the concentration coefficient and hence these are two independent parameters.

Noteworthy, employing triangular pyramids as optical elements allows the formation of acceptance apertures having a hexagonal symmetry as illustrated in FIG. 4e, which in turn allows the formation of tight ensembles of concentrators into panels with various arrangements such as planar, semi-spherical, cylindrical, etc.

Nesting of Optical Elements

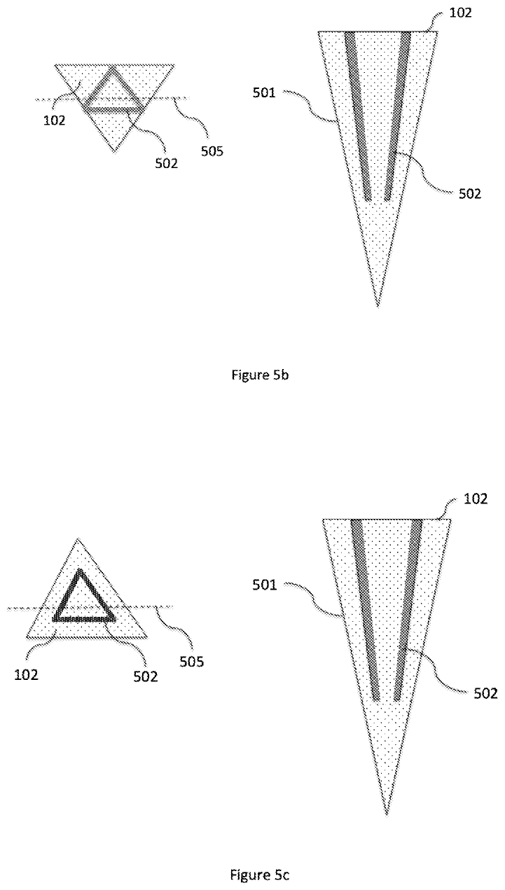

It is noted that so far we have considered the optical elements as monolithic bodies. A further development represents nesting of optical elements in such a way that the nested optical sub-elements do not necessarily run through the whole height of the parent optical element (i.e. they are generally truncated at the apex) as illustrated in FIG. 5a which represents schematically the side view (left) and top view (right) of an optical element representing a hexagonal pyramid. Specifically, the hexagonal pyramid 500 (also referred to as parent optical element) is internally divided into smaller truncated triangular pyramids 501 by dividing walls 502 made of a lower refractive index material and of thickness 503. The side view (left) is taken along the direction 504. The dividing walls 502 define (play the role of) the gaps between the triangular pyramids 501. As noted above, the dividing walls 502 do not necessarily reach the apex of the parent optical element resulting in that all nested optical elements physically share the apex of the parent optical element. The latter has a number of advantages including those presented in relation to FIG. 3m above. On the other hand, the virtual apex angles of the thus formed triangular pyramids 501 are smaller than that of the parent optical elements 500. This results in smaller optical sub-element images the union of which is smaller than the area of the parent optical element image 300. The second effect of nesting optical sub-elements is that it results in an increased number of interfaces between the optical elements which as discussed above skews the intensity of the exit light flux towards the center of the parent optical element image 300. Not the least, the preservation of the relatively larger apex angle of the parent optical element has certain technological benefits. Lastly, nesting may be multilevel, that is, the optical sub-elements 501 may be further subdivided into smaller optical sub-elements in the same manner as illustrated schematically in FIG. 5b. Specifically, it shows a top view (left) and a side view (right) of the arrangement of the dividing (peripheral) walls 502 as the latter join the triangular front surface 102 (left). The right half shows a cross-section perpendicular to the front surface 102 and containing line 505. Again, the newly formed sub-elements do not necessarily run through the whole height of the parent sub-element. Another example of nesting is illustrated in FIG. 5c where the nesting is done in a concentric manner but otherwise analogously to FIG. 5b. The nested exit-walls may or may not be parallel to the parent exit-walls.

Loss Mechanisms

We now consider typical loss mechanisms in the light concentrator excluding the primary escape-cone effect discussed above. These losses are divided into two categories, propagation and rejection losses respectively. The propagation losses result in energy deposition in the concentrator while rejection losses represent the light intensity returned back to the ambient. The first category includes mainly absorption losses along the propagation path of the rays and absorption losses in the peripheral mirrors. Noteworthy, the propagation losses are dispersive, i.e. a function of the wavelength, as are the indices of refraction for that matter. All these are materials and technology related issues common to all optical systems and are outside the scope of the current invention apart from mirror losses which in this specific case may be mitigated in a number of ways. Clearly, one obvious implementation is the use of various types of metallic mirrors as is well established in the art. Another solution for very high end application is the use of Bragg reflectors with an appropriate bandwidth in the wavelength range of interest. A third solution is to employ various combinations between metallic and Bragg reflectors. One such approach is the so called layered reflectors where the reflecting layer consists of two sub-layers, one being a thin metallic film and a second, on top of the first one, representing a partial Bragg reflector. A further approach suitable for the current invention is the use of a sectorial (mixed type) mirrors where the topmost section near the entrance aperture is a metallic mirror while the bottommost section near the exit aperture where the light density is highest, represents an appropriate Bragg mirror.

As for the rejection losses these include reflection losses at the front surface 102/air interface (unless an antireflection coating is applied), light scattering in the bulk and from interfaces due to surface roughness, impurities, particle inclusions, contaminations, etc. One type of rejection loss, i.e. secondary escape-cone effect, already discussed in reference to FIG. 3b, is always present for rays propagating within an optical element. A similar secondary escape-cone loss mechanisms also exists for rays propagating between optical elements. Specifically, any combination of exit-wall faces, including mirror faces, may define a virtual cone for such rays and hence the latter experience the familiar escape-cone effect. Here again, the intensity of the reflected rays falls off exponentially between successive reflections but nevertheless the effect is always present. As a general rule for mitigating this effect (both inside and between the optical elements) is decreasing the apex angle and increasing the number of interfaces.

Concentrator Fabrication

The individual optical elements and associated adjoining elements (fixtures, spacers, gaps, exit plate, protective screen, etc) are fabricated of standard optically transparent materials. Typically, but not exclusively, such materials are optically transparent polymer glasses such as PMMA, PC, PS, PE, etc, optically transparent liquids such as water, diols, triols, etc and their mixtures including flame retarding additives, inorganic glasses (SiO₂, BSG, fused quartz, Al₂O₃, AlN, etc), semiconductor materials (Ge, Si, GaAs, ZnSe, ZnS, MgF₂, CaF₂, BaF₂, CdTe, etc), gases such as air, nitrogen, argon, etc, aerogels, etc. Where relevant, the materials are UV stabilized to eliminate degradation during prolonged solar exposure.

The fabrication methods depend on the specific materials and generally, but not exclusively, include casting, moulding, extrusion, polymerization, polishing, etc and their derivatives such as injection moulding, plastics extrusion, stretch-blow moulding, thermoforming, compression moulding, calendering, transfer moulding, laminating, pultrusion, vacuum forming, rotational moulding, etc as well as their variations. These methods are well established and routinely used in the art. All surfaces should preferably be optically flat to reduce light scattering. In cases where the fabrication process does not provide sufficient surface finish the optical surfaces may be thinly coated by a suitable method, say a monomer (PMMA, PC, etc), say, by spraying followed by a standard polimerisation step or other methods such as deposition of suitable thin films, most notably amorphous films such as SiO₂, Al₂O₃, etc. Alternatively, optical surfaces may be chemically/mechanically polished to the desired smoothness.

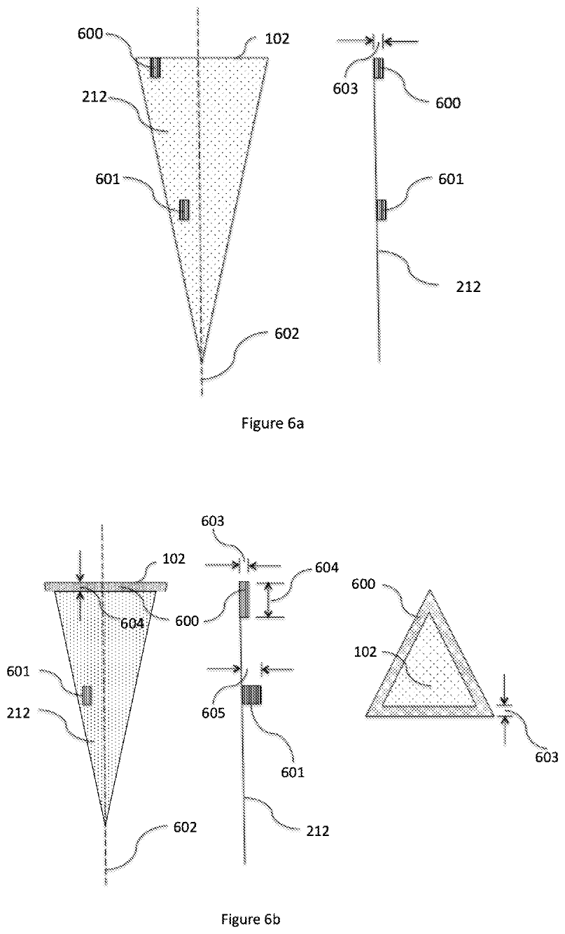

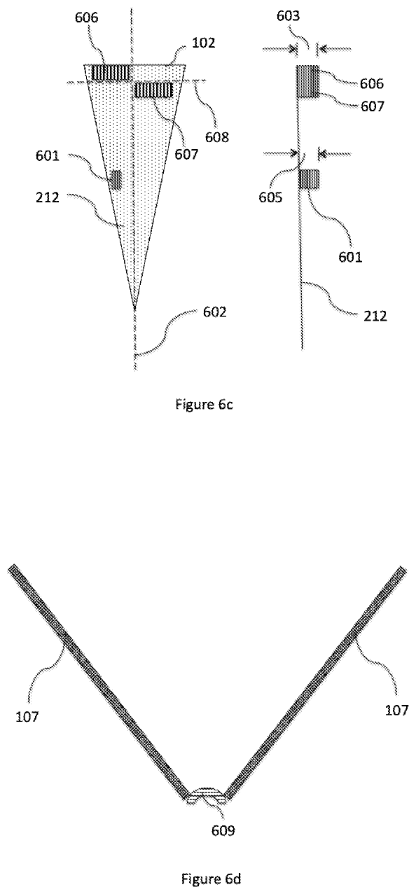

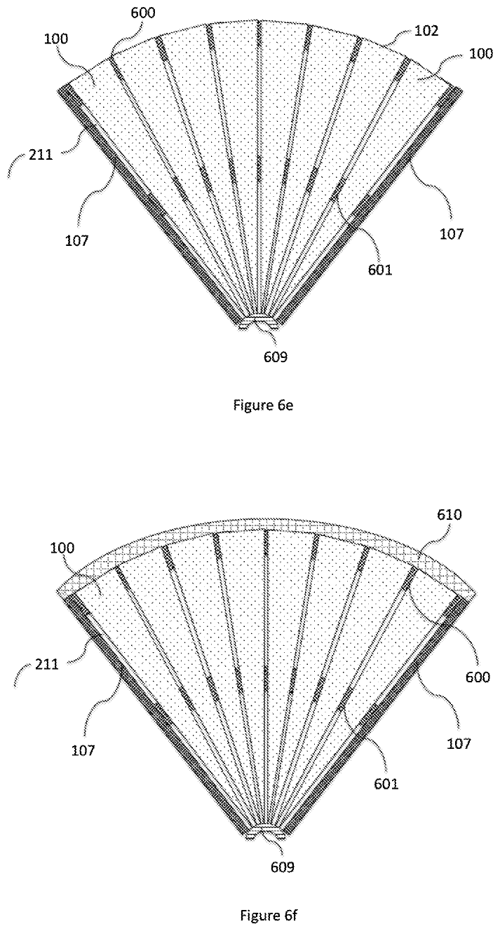

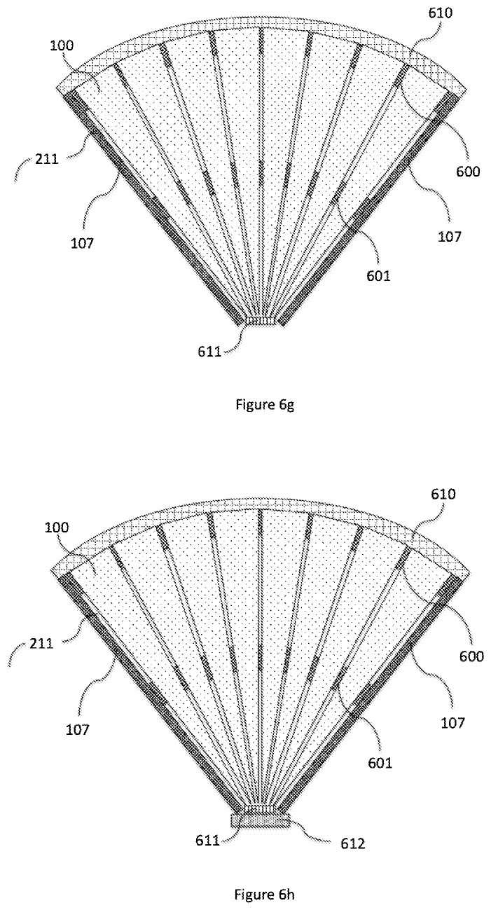

Some specific aspects of the fabrication of the concentrator are related to gap definition and concentrator assembly. In here, we describe schematically some general methods based on the use of spacers for the definition of the gaps. Specifically, FIG. 6a represents the front view (left) and the side view (right) respectively of the exit-wall 212 of the an optical element 100 representing a triangular pyramid. Two spacers (protrusions) 600 and 601 of specific dimensions are positioned anti-symmetrically with respect, say, to the central axis 602 (or any other axis lying in the plane) of the exit-wall 212. Anti-symmetric positioning with respect to a given axis means that the symmetric image of the spacer with respect to the same axis is void, i.e. there are no spacers placed on the spacer's image position. In this way, when two exit-walls are brought into close contact each anti-symmetrically positioned spacer will contact the empty image on the opposite (contacting) exit-wall. Symmetric positioning is the case where a spacer has an identical (or complementary) image symmetrically positioned with the respect to the line of symmetry. Symmetric positioning may also be advantageous as illustrated in FIG. 6b. Specifically, the spacer 600 now represents a continuous strip which extends from one edge of the exit-wall 212 to the other and has a height 604 (FIG. 6b left) as well as a thickness 603 (FIG. 6b middle) which is twice smaller than the thickness 605 of spacer 601. The latter is anti-symmetrically positioned and hence has a width 605 exactly equal to the gap width. Anti-symmetric positioning allows face interlocking of the two contacting surfaces resulting in automatic alignment as illustrated in FIG. 6c. Specifically, spacers 606 and 607 are positioned anti-symmetrically both with respect to the central axis 602 of the exit-wall as well as with respect to line 608 perpendicular to central axis 602. The distances of spacers 606 and 607 to lines 602 and 608 respectively are determined by fabrication margins. Clearly, upon contact between two neighboring exit-walls the faces will interlock in both directions, thus resulting in automatic horizontal and vertical alignment of the optical elements. The spacer configurations illustrated in FIG. 6a,b,c are used in a number of preferred embodiments. Most generally, spacers are made as small as possible and designed to introduce minimum light scattering. The importance of light scattering increases as the distance to the exit aperture decreases. In the first place this is achieved by minimizing their non-essential dimensions (i.e. perpendicular to the gap width) and/or using a geometry to the same effect. Spherical spacers in this context represent good candidates as they have a minimal contact surface with the exit-walls.

Further, in a next step the mirror structure 107 is fabricated having optionally a temporary support element 609, FIG. 6d. The element 609 serves to support and align vertically the optical elements 100 as they are inserted into the mirror structure 107. In this way the optical elements are self-assembled in a tight manner with the spacers automatically defining the gaps between them as illustrated in FIG. 6e. In a next step the optical elements are permanently fixated. To this end, the formation of a (optional) chemical/fusion bond between the spacers and opposite optical elements provides rigidity to the structure. This can be achieved by standard thermo/chemical/optical bonding processes. The rigidity is further enhanced by the definition of a protective optically transparent screen 610 which is hermetically bonded/glued to the front surfaces 102 of the optical elements 100 all the way to and including the mirrors 107 as illustrated in FIG. 6f. The screen 610 is preferably made of an optical material of a similar to the optical elements refractive index material and may be scratch resistant and have an antireflective coating. Apart from protecting the concentrator from the environment the screen provides rigidity to the structure in addition to decreasing the thermal conductivity between the input and the output of the concentrator. It is clear that the protective screen 610 does not affect the functional properties of the optical elements as it merely acts as an interface between the incident light and the front surfaces of the optical elements. In preferred embodiments its shape is circular with a radius equal to the radius of the concentrator. Other more complex shapes are also admissible. At this stage, the supporting element 609 is safely removed and subsequently a (optional) retractable mirror (or metal reflector, also called shutter) 611 is positioned in its place as illustrated in FIG. 6g such that it moves freely in the space between the tips of the optical element and the underlying exit plate 612 (see FIG. 6h). The retractable mirror 611 is used to cut off light (reflect it back to the ambient) when needed (in emergency, shutdown, etc). The exit plate 612 conceals hermetically the whole concentrator as illustrated in FIG. 6h and provides an additional thermal insulation from the eventual light absorber (a solar cell or light-to-heat converter). Alternatively, the role of plate 612 may be adopted by the latter. The order of positioning the shutter and the exit plate depends on the specific application.

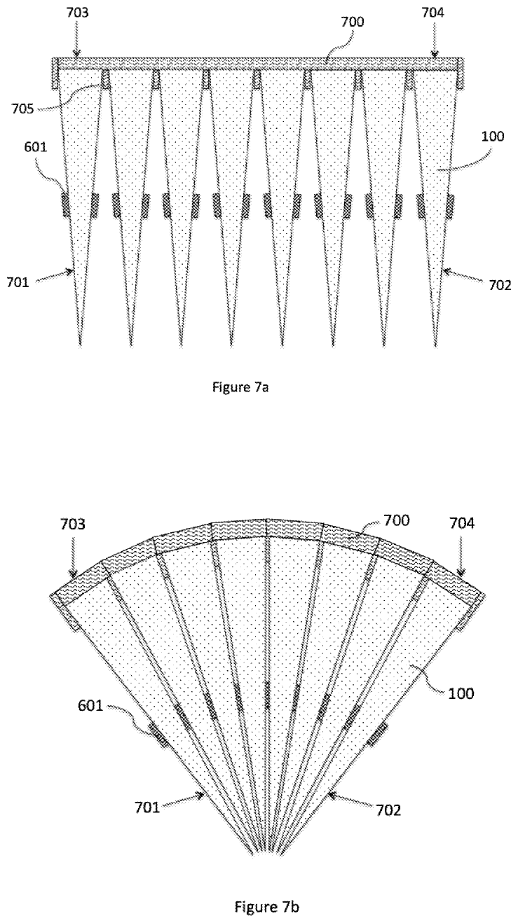

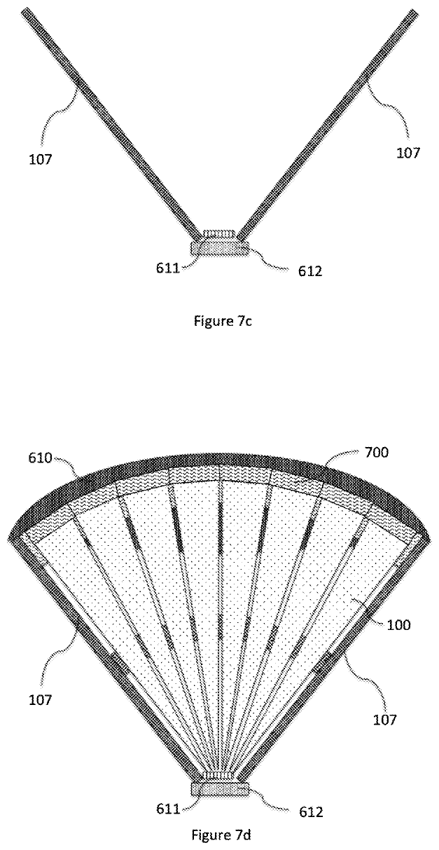

FIGS. 7a,b,c,d illustrates a further fabrication method. Specifically, the optical elements 100 are positioned and/or glued/bonded by a robotic arm at specific positions onto a planar fixture 700 which is thermally compliant (preferably at a lower temperature than that of the optical elements and preferably of a similar refractive index to that of the optical elements). Positional delineators 705 define the positions of the optical elements as well serve as spacers 600 although their use is not imperative in view of the bonding process between the optical elements 100 and the planar fixture 700. Further, upon mild heating the planar fixture 700 becomes compliant to deformation and hence by applying deformation forces in specific directions indicated by the arrows 701, 702, 703 and 704 the whole structure adopts (folds into) its final configuration in FIG. 7b. Noteworthy, the planar fixture may be suitably perforated to increase compliance and enhance transition from a planar to a curved surface. Next, the peripheral mirror structure 107 together with the (optional) retractable mirror 611 are fabricated in a separate step as illustrated in FIG. 7c. Finally, upon (optional) fusion of the optical elements (bond formation with the spacers) and cooling the structure from FIG. 7b is inserted into the mirror structure 107 and hermetically sealed from the ambient by a protective screen 610 as illustrated in FIG. 7d.

In a preferred embodiment, automated assembly of the concentrator is done by a robotic arm such that the faces of the front surfaces 102 are attached to individual fingers of the robotic arm (similarly to FIG. 7a) which in turn maneuvers the optical elements into their final positions thus forming the core of the concentrator in one step (similarly to FIG. 7b). Thus, the role of fixture 700 is performed by a robotic arm with suction fingers which inserts all optical elements simultaneously into the mirror structure thus eliminating the need for a planar fixture.

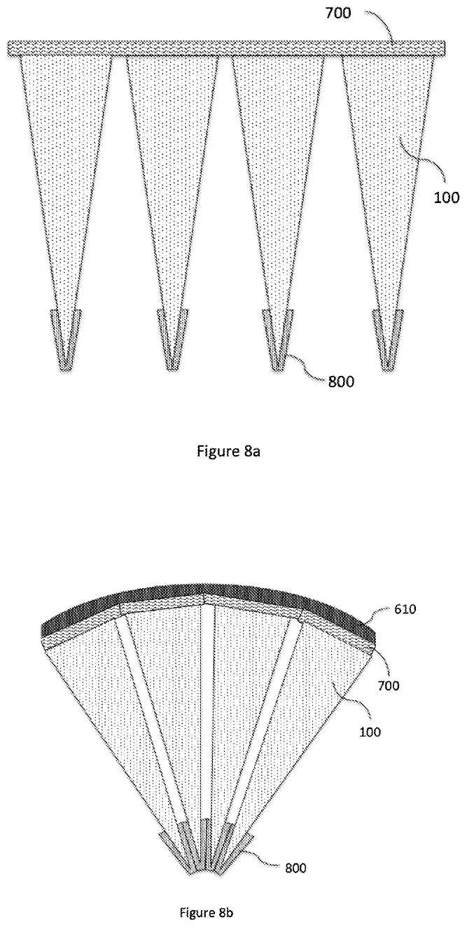

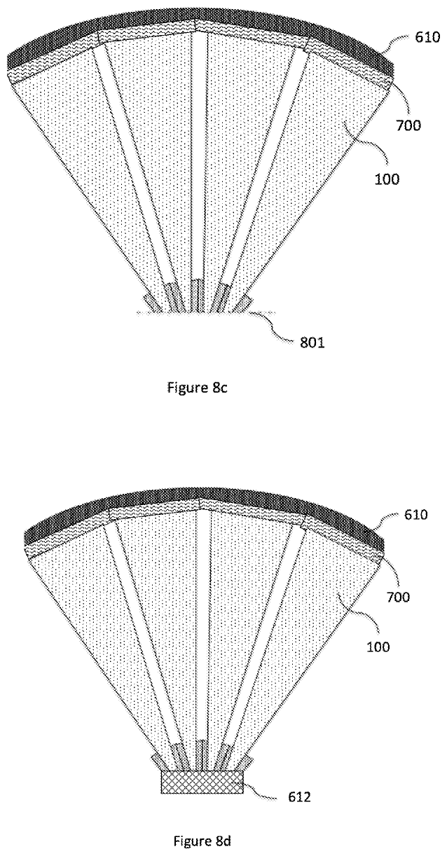

The assembly methods presented in FIGS. 6 and 7 above make use of spacers which, however small in dimensions, inevitably introduce perturbations and hence contribute to light scattering. For high end applications it makes sense to eliminate the spacers at position 601. One way of achieving this is by using sacrificial spacers 800, typically, positioned at or in the vicinity of the apex as illustrated in FIG. 8a. The sacrificial spacers 800 may be fabricated of, say, ice, dry ice, wax, paraffin, camphor, phthalic anhydride, caffeine, naphthalene, stearic acid, sodium stearate, etc, that is, materials easy to remove by sublimation, melting, dissolution or etching. Next, analogously to FIG. 7b, the structure is folded into its final configuration followed by the definition of the protective screen 610 as illustrated in FIG. 8b. The protective screen at this stage provides structural integrity and stability allowing a subsequent planarization of the tips of the optical elements by an appropriate cutting method at an appropriate level 801 as illustrated in FIG. 8c. Final structural stability is provided by the exit plate 612 which is bonded (glued) to the planarized tips of the optical elements as illustrated in FIG. 8d. The final step is removal of the sacrificial spacers 800 resulting in a spacerless core as illustrated in FIG. 8e. The assembly proceeds by inserting the thus fabricated core into the mirror structure 107 followed by encapsulation. The retractable mirror 611 in this case is mounted below the exit plate 612.

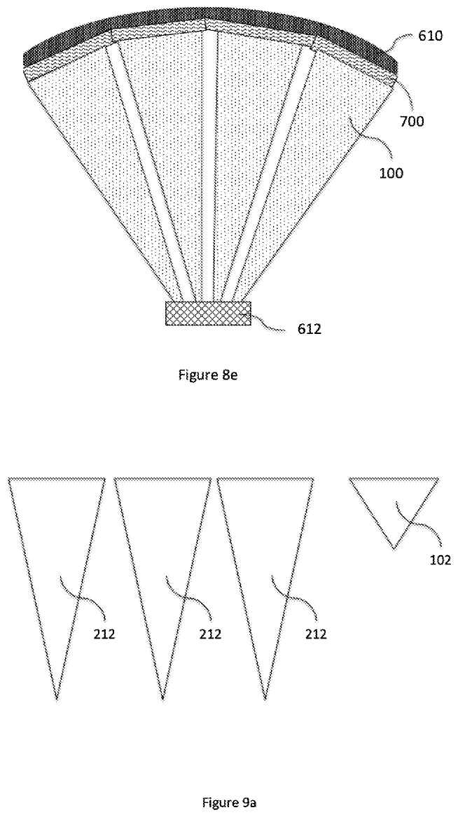

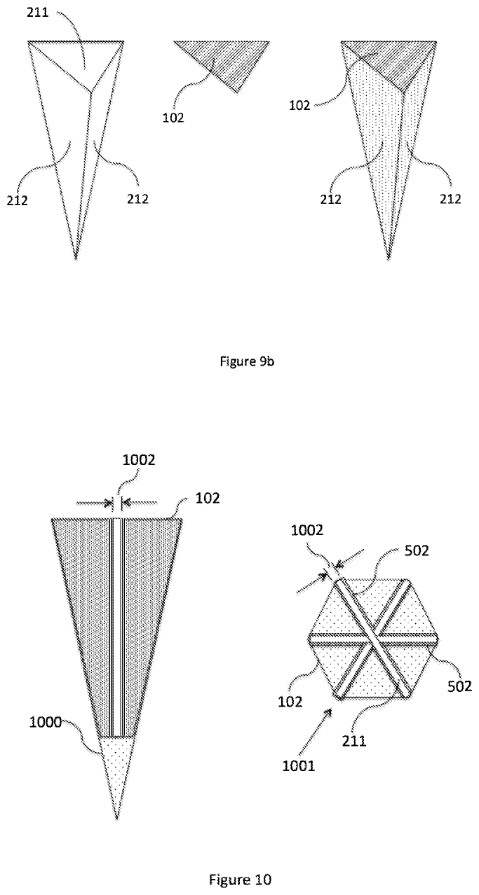

In one preferred embodiment of the concentrator the walls of the optical elements are made of a solid optical material while the inner volume is filled with an optically transparent liquid. One method for the fabrication of such optical elements is first fabricating the individual exit-walls 212 and the front surface 102 of the optical elements from sheets of the optical material of choice as illustrated in FIG. 9a. This is followed by a subsequent fusion of the exit-walls into the desired 3D shape (empty pyramid in this case) through a suitable thermal/chemical/optical gluing method as illustrated in the left side of FIG. 9b. Naturally, the starting material (sheets) should have sufficient optical surface finish and if needed with spacers defined at designated locations. Alternatively, the spacers may be fused/glued after cutting of the exit-walls. In a preferred embodiment, the hollow optical element along with spacers (FIG. 9b left) is fabricated in one step by stretch-blow moulding or any other suitable method. Next, the inner volume is filled with the optical liquid of choice and finally the pyramid sealed by the front surface 102 through a suitable fusion/gluing method as illustrated in the rightmost part of FIG. 9b. Nesting in this case is achieved by making the dividing walls 502 hollow and filled with air (gas) as illustrated in FIG. 10 which depicts an optical element with the shape of a hexagonal pyramid 1000 in a side view (left) along direction 1001 and a top view (right). The gap thickness is now defined by the thickness 1002 of the air gap within in the dividing walls 502. All this makes fabrication of nested optical elements straightforward in this case and reduces the use of spacers. Thus, the dividing walls 502 may be first attached (glued) to the hexagonal front surface 102 and inserted into the hexagonal pyramid 1000 already filled with an optical liquid prior to that analogously to FIG. 9b, followed by an encapsulation step. Concentrator fabrication may then proceed along any of the paths in FIGS. 6,7,8. It is noted that filling small volumes (e.g. the tip of the optical element) with liquids may be hampered by surface tension and air trapping. In such cases the tip of the optical element around is made of the solid optical material to reduce curvature and alleviate the problem. In fact, nesting also addresses this issue since the tip angle is larger than the projected apex angles of the child optical elements. Other approaches include vacuum processing, wetting, etc. In all cases, where at least one optical material is liquid a diffusion barrier may be needed to alleviate eventual permeability problems. This is normally done by suitable thin film coatings at appropriate interfaces.

Another variation of the methods in FIG. 9a,b and FIG. 10 (not illustrated for brevity) is to fill the volume of the optical elements with an optical material of a higher refractive index than that of the walls (102 and 212) which automatically results in a “spacerless” assembly since the walls (102 and 212) in this case upon contact play the role of the gaps. Gluing the optical elements in this case is desirable since it provides rigidity in addition to eliminating the necessity for encapsulation. Clearly, the thickness of the walls should be at least half of the intended gap width since this is a case of symmetric spacing. With respect to the geometry of FIG. 10 the dividing walls need not be hollow but made of the same material as the walls (102 and 212) of the optical element and have the intended gap width thickness.

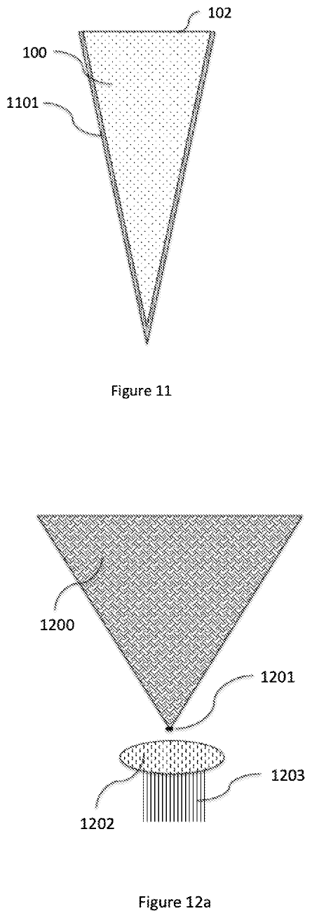

An alternative way of achieving a “spacerless” assembly is illustrated schematically in FIG. 11. Specifically, a thin film 1101 of the lower optical index material is deposited/glued on the exit-walls 102 of the optical elements 100 with a thickness at least half the intended gap width as shown in FIG. 11. This, again, is a case where symmetric spacers cover fully all exit-walls. After that the process continues according to the sequence shown in FIG. 6d,e,f,g,h. An environmental screen 610 and a shutter 611 and an exit plate 612 may still need to be defined.

Needless to mention that the fabrication steps above prior to final encapsulation are done in a dust free environment to prevent contamination of all optical surfaces.

### Very High Concentration Diffuse Light Concentrators

Achieving very high concentrations with diffuse light concentrators is feasible since the concentration coefficient is primarily determined by the area of the exit aperture of the peripheral mirrors. Clearly, this exit area can in theory be made very small. The most efficient way of achieving this is by minimizing the width of the gaps. Another way is by extending the exit aperture beyond the tips of the optical elements although this would result in proportionally increased rejection and propagation losses. Nevertheless, such a possibility is feasible. Further, operating high flux densities in close proximity with the exit aperture of the concentrator is often impractical which necessitates that the concentrated light flux be transported at some distance to the absorber. To this end as noted above, diffuse light concentrators can be designed in such a way that the angular distribution of the exit light flux is sufficiently narrow such that when fed into an appropriate waveguide the flux propagates through total internal reflection. In other words, the flux is waveguided without loss. Even more so, the angular distribution of the concentrated flux can be designed sufficiently small as to allow the definition of a certain curvature in the waveguide without disobeying the condition for total internal reflection. Thus, one option for transporting concentrated light fluxes represents appropriate light waveguides which, as well known in the art, consists of a core (high refractive index material) and a padding (low refractive index material) appropriately selected to satisfy the total internal reflection condition for all rays (modes) in the exit flux.

Further, in specific cases the spot size of the exit flux can be made sufficiently small (virtually a point source) which then can be parallelized with standard imaging optics as schematically illustrated in FIG. 12a. Specifically, it represents a diffuse light concentrator 1200 with a sufficiently small exit spot size 1201 which lies at the focal point of an imaging collimating system 1202. The parallelized flux 1203 can then be transported at extended distances. Clearly, the collimated exit flux attains a smaller flux density due to the increased diameter after collimation but the important aspect here is parallelization in view of transporting the flux at extended distances where it can be refocused again if needed. Naturally, the use of low loss optical materials, particularly in the concentrator 1200 and the imaging optics 1202, is essential for the wavelengths of interest.

Another way to achieve very high flux concentrations is to cascade (serially connect) several concentrators as illustrated schematically in FIG. 12b. Specifically, it represents a series of level 1 concentrators 1200 the outputs of which are fed by appropriate waveguides 1204 onto the input of a second level concentrator 1205. Obviously, for highest concentration the diffuse image 104 of concentrator 1205 should be completely covered by waveguides 1204. In practice this means that waveguides 1201 fully cover the protective screen 610 with which they are also in intimate contact to reduce reflection losses. The concentrators 1200 are assumed identical, although this is not imperative. Concentrator 1205 may also have a different geometry and concentration coefficient. Obviously, the net concentration coefficient is the product of the concentration coefficients of the first and second level concentrators. Here again, one might use imaging optics to parallelize the exit flux. Clearly, collimated light fluxes can now be transported at extended distances through low loss optical media such as air, vacuum, etc and used in a variety of applications, including in several described in this disclosure. In a different implementation the exit flux from collimators 1200 and 1205 may be used directly or fed into a waveguide for further use.

### Applications

Clearly, the diffuse light concentrator described above has potentially a wide range of application areas particularly in such areas where high energy densities are needed. In here, as an illustration we consider three major categories, namely energy harvesting from solar radiation, energy storage, as well as a few assorted applications as follows.

### Harvesting of Sunlight

### Electricity Generation

Direct electricity production using diffuse solar concentrators is straightforward by attaching a (solar) photovoltaic cell 1300 to the exit plate 612 (or in place of it) of the concentrator thus forming a Concentrating Photovoltaic (CPV) cell as illustrated in 13a. The solar cell may be either a single or multiple junction solar cell specifically designed for the intended solar concentration and temperature of operation. As the contact between the solar cell and the exit plate is intimate no antireflection coating is needed between them, provided optical matching is included in the design of the solar cell. Optionally, the solar cell 1300 may directly replace the exit plate 612. Further, at high solar concentrations active cooling may be needed. The actual dimensions of the CPV cell are determined by the size of the solar cell and the required concentration in addition to the requirement that the CPV cell does not occupy too large a solid angle. Thus, a 1 cm² solar cell and a concentration factor of 100 require an acceptance area of 100 cm². This results in an approximate height of the optical elements of about 10 cm. Arrays of CPV cells can then be assembled onto supporting frames of suitable dimensions forming so called CPV panels where the solar cells in the CPV cells are connected electrically, both in series and in parallel schemes. The panels may have various arrangements such as planar (i.e., all CPV cells lie in a plane), semi-spherical, cylindrical (all CPV cells lie on an upright cylinder). Further, the panels are arranged in arrays thus defining a CPV power plant. Naturally, as is customary in the art, the constituent CPV cells arranged in panels and arrays are electrically matched through blocking and bypass diodes to reduce mismatch electrical losses due to non-uniform illumination.
Further, as the current efficiency of the solar cells is dismally below 100% it makes a lot of sense to combine the above solar power panels with active cooling (heat exchange and transport) in a combined system which is known as cogeneration, that is, combined electricity and heat generation. Such systems are also called concentrating photovoltaic thermal (CPVT) systems. This would be in general low grade heat which can be used for heating purposes, although additional electricity generation from a Sterling engine for instance is also feasible. In addition, keeping the solar cell under controlled temperature improves its performance as well. At this stage one can discern two groups of applications, consumer and industrial power generation respectively.

### Consumer CPV and CPVT Solar Power Plants

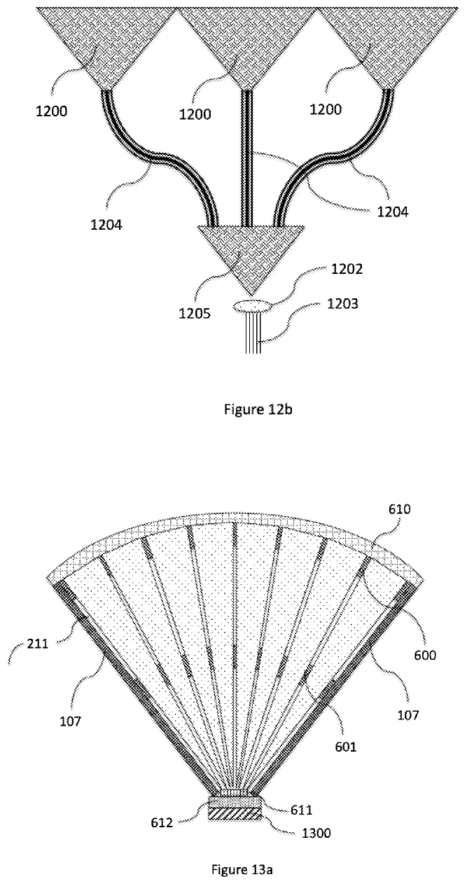

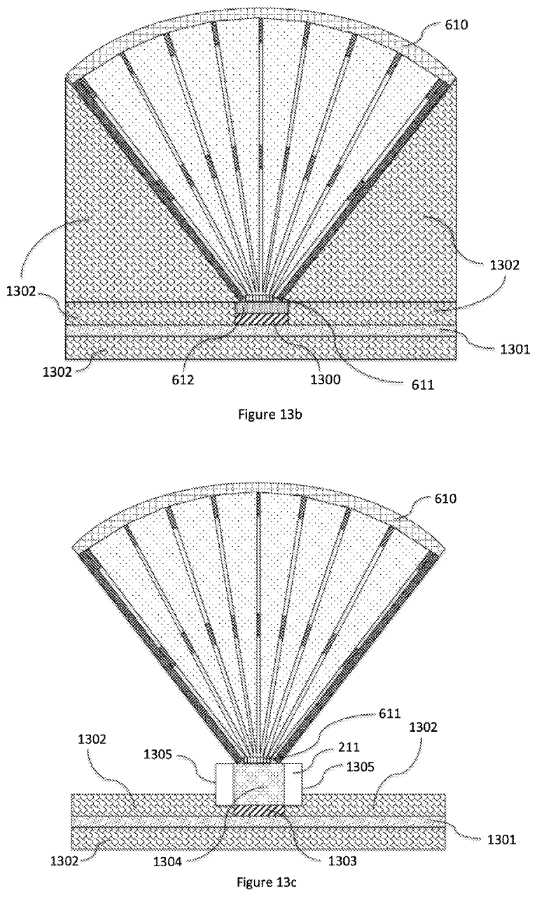

Stand-alone CPV systems are an obvious product provided solar concentration is low enough to allow operation without cooling. Nevertheless, it is likely that CPV systems will compete with CPVT systems which in addition to electricity generation make use of the residual (waste) heat. In this case, the latter is to be used for heating of homes, offices, greenhouses, etc as well as to accumulate heat in a heat reservoir for short term use. One obvious example for a heat reservoir is a thermally insulated water tank or another suitable fluid. The heat reservoirs may have a dual use, namely, in cooler seasons they accumulate heat from the sunlight for use at night, and in warmer seasons, they dissipate heat nighttime for daytime cooling purposes, respectively. FIG. 13b illustrates schematically a typical CPVT cell where the heat from the solar cell 1300 is transferred to a circulating thermal carrier 1301 (high heat capacity fluid) which is further thermally connected to a central heating system, heat consumer, heat sink or similar. The essential element here is the overall thermal insulation of the solar cell 1300 from the ambient which is provided by both the solar concentrator itself as well as the thermally insulating elements 1302 as illustrated in FIG. 13b. This thermal insulation results in efficient harvesting of the waste heat from the electricity generation process.

Further, the solar cell 1300 may be replaced by an efficient light-to-heat converter resulting in a consumer version of Concentrating Solar Thermal (CST) systems discussed below. Two cases are of practical interest here as follows. In the first instance the system can be designed to generate low/medium/high grade heat which in turn is used to drive a Sterling engine for electricity generation. The waste heat from the Sterling engine is then used for heating purposes. In the second instance, the system can be designed to generate low grade heat in which case the latter is used for heating purposes only.

### Industrial Concentrating Photovoltaic Thermal (CPVT) Power Plants

Most likely, CPVT systems would employ more expensive but also more efficient multiple junction solar cells. Such cells allow somewhat higher operating temperatures. Nevertheless, this is still low grade heat and most likely is to be used for heating purposes if close to a community or other heat consumers. In other cases, such power plants are advantageously erected in pairs with greenhouse complexes to provide both heating and lighting. As efficiency in this case is important (even at the expense of cost) a rudimentary form of sun tracking here would be preferable solely for maintaining maximum exposure area to direct sunlight as the sun traverses the sky. Precision here is absolutely not an issue as long as the cosine of the misalignment angle is not vastly different from 1 since the sole purpose of tracking here is maximizing the illuminated projected area. Tracking in such a case can be preprogrammed for the specific geographic location and time of the year. In other words, no real time sensor tracking is necessary and a misalignment angle of +10 degrees is quite acceptable for most practical situations.

### Industrial Concentrating Solar Thermal (CST) Power Plants

FIG. 13c illustrates a CST cell where the solar cell 1300 in FIG. 13a is replaced by an efficient light absorber 1303. Thus, the high grade heat generated in the CST cell is transported by the carrier fluid 1301 to a steam producing heat exchanger and which steam in turn drives steam turbines or other thermo-mechanical engines. Approximate sun tracking as described above in this case is also desirable. One issues here is the construction of an efficient thermal insulation of the concentrator from the light absorber as well as achieving a sufficiently high thermal insulation between the heat transporting fluid and the ambient. As indicated above, diffuse light concentrators can be designed so that their exit fluxes can be waveguided in an appropriate waveguide. In terms of CST systems this allows the use of a waveguide 1304 which provides thermal insulation of the concentrator from the light absorber 1303 as illustrated in FIG. 13c. The waveguide 1304 is inserted in a concentric cylinder filled a low refractive index material (typically air). Horizontal barriers inside the latter may be defined to reduce convection. Naturally, the waveguide 1304 is made of an optical material able to withstand the intended operating temperatures and thermal gradients. Examples for such materials are high temperature glasses, fused silica, quartz, etc. Alternatively, thermal insulation can also be achieved by collimating the exit flux (as discussed above in connection with FIG. 12) and transporting it through air to the light absorber. Most likely, the concentrators themselves need not be thermally insulated from the ambient in this case as it is desirable they be kept at ambient temperature.
As already noted all systems above (CST, CPVT, etc) may employ some form of sun tracking which naturally increases their efficiency due to increased exposure area to direct sunlight for which reason such systems are also referred to under the general term as Concentrating Solar Harvesting Systems.

### Conversion/Storage of Concentrated Solar Radiation

The diffuse light concentrator technology and CST in particular is well suited for short term storage as it allows the generation of high grade heat (high temperatures) and hence allows an efficient and compact short term storage of energy. Examples of short term storage are the use of molten salts, hot water, etc. Long term storage, however, requires lossless storage. In this respect chemical energy storage is one very suitable approach. Typical examples are water splitting (photocatalytic, photoelectrochemical, thermochemical such as Ce oxide cycle, Cu chloride hybrid cycle, etc), Ca(OH)₂—CaO, metaloxides redoxcycles, sulfur cycles, dehydration, etc. Here again, the diffuse light concentrators are well suited for such applications.

### Assorted Applications of Concentrated Solar Radiation

### Materials Synthesis and Processing

The ability to heat materials to high temperatures with concentrated solar (or artificial) radiation opens yet another way for materials processing, thermal decomposition, synthesis, deposition, welding, melting, etc employing the present invention. Further, surfaces thus can be heated optionally in the presence of reactive gases, altering thus their chemical composition and/or crystallographic structure. Thus, a range of surface coatings can be produced in this way. Highly concentrated radiation (solar or artificial) can also be used for evaporation of materials and hence for the deposition of thin films. Evaporation can also be done in a reactive atmosphere allowing thus the deposition of a range of compounds, for instance, oxide, nitride coatings, etc.

### Water Desalination/Purification

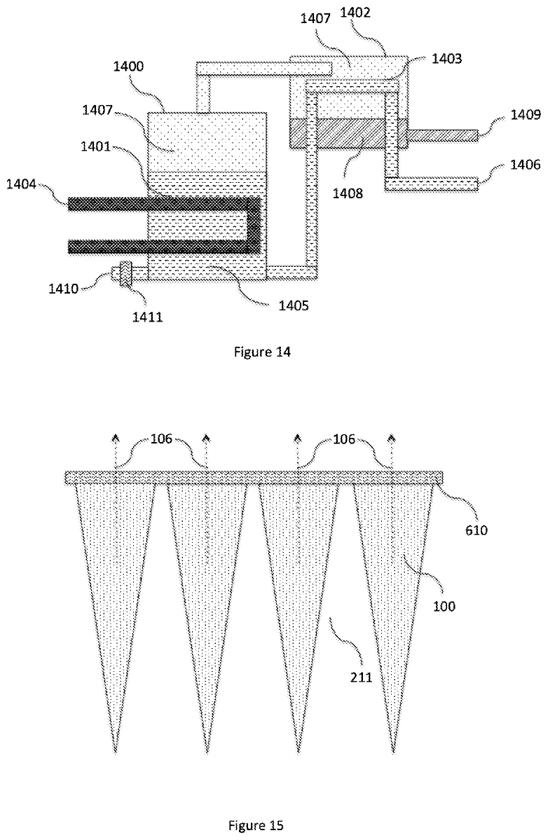

CST can be effectively applied to desalination of sea, brackish or contaminated water. A number of desalination methods may be suitable amongst which solar distillation appears to have a great potential since it makes direct use of solar radiation in addition to that condensation energy can be reused to pre-heat salt water. Salt water evaporation can be done directly by concentrated solar radiation or indirectly through heat. A schematic of an indirect desalinating system is presented schematically in FIG. 14. It consists of an evaporator 1400 with a heat exchanger 1401, condenser 1402 with a heat exchanger 1403.
The hot carrier fluid 1404 from a CST plant is fed into the heat exchanger 1401 where it heats and evaporates salt water 1405 which is fed initially into the system through inlet 1406. Further, the steam 1407 generated in the evaporator 1400 is fed into the condenser 1402 where it is condensed by the incoming cool salt water through inlet 1406. The condensed distilled water 1408 is discharged from the system through outlet 1409 for further use. The byproduct (concentrated salt water) is periodically or continually discharged through outlet 1410 in conjunction with valve 1411. Certainly, this is just a principle description and the novelty here is the use of CST systems as described above with existing desalination methods (both direct and indirect) for water desalination/purification.

### Illumination

The possibility of waveguiding (i.e. transporting) concentrated light fluxes from diffuse light concentrators allows direct use of solar light for interior illumination with natural light in buildings, greenhouses, etc. Diffuse light concentrators in conjunction with optical waveguides can be used for providing daylight illumination to the interior of buildings due to their higher efficiency and lower specific cost. Diffuse light concentrators or rather panels of such allow also the construction of greenhouses with thermally insulated walls and roofs while lighting being provided directly or via waveguides. This would reduce substantially the heating costs as well as that for artificial lighting.

### Laser Pumping

Lasers are pumped by various sources (light, electricity, etc). Since excitation is a probabilistic process optical pumping normally takes place in an optical cavity (resonator) to increase the efficiency of excitation which is balanced by de-excitation. Thus, to achieve a high level of inversion intense light sources such as flash lamps are needed. Diffuse light concentrators have a great potential in this respect by providing intense light sources.

### Façade and Roofs in Construction Engineering

One other possible application is installing the above described solar power panels, CPVT and CST in particular, not only on building roofs but on the façades of buildings as well. This not only increases the total area of the power plant but also provides additional/complementary thermal insulation to the building. Clearly, the biggest advantage with respect to current PV solar panels in this case is the heat generation for heating the building in the cooler months of the year as well as for hot water. Excess heat in the warm months, unless utilized for other purposes, may naturally be dumped back into the ambient leading to reduced cooling needs since this very heat would have otherwise gone for heating the building itself. A further advantage of vertically mounted panels is their independence of snow cover.
It is also noted that all solar panels consisting of diffuse solar concentrators discussed in all applications above in addition to the retractable shutter 611 are optionally provided with additional safety mechanisms. One such mechanism is provided by blinds which are activated automatically and cover fully the panels in case any of the retractable shutters fails. A further safety mechanism is provided by non-transparent and insoluble in water paint which is sprayed automatically over the panels in case any of the blinds fails.

### Directional Illumination

A diffuse light concentrator with a concentration coefficient of approximately 1 is illustrated in FIG. 15 where the axes 106 of the individual optical elements are approximately parallel to each other. Such an arrangement is not meant to provide significant concentration, if any, of light but merely acts as a downward angular transformer of diffuse light incident onto its top surface (protective screen 610). In other words, the diffuse light flux incident onto the screen 610 with an angular distribution in the range (−π/2, +π/2) with respect to the normal 106 is transformed upon exit approximately into a narrower angular range (−ψₘₐₓ, +ψₘₐₓ) where ψₘₐₓ<π/2 in accordance with the present invention. The primary use of such an arrangement is directional illumination from a diffuse light flux. The absolute dimensions of the optical elements in this case are made as small as possible but still within the validity of geometrical optics. Typically, the dimensions of the optical elements lies, although not exclusively, in the millimeter and sub-millimeter range. In practice, their dimensions are to be determined by the fabrication technology and cost. Since light concentration in this case is of no concern such an arrangement is called diffuse light transformer, i.e. it transforms a diffuse light flux into a more directed light flux. The total thickness of the diffuse light transformer is solely determined by the specifications of its use and typically concern its mechanical properties. As indicated, the primary use of such a transformer is directional illumination from diffuse light and hence it extends arbitrarily in the lateral directions, i.e. its area is arbitrary. Thus in practice, a diffuse light transformer represents a transparent sheet made of a relatively high refractive index material such that one of its surfaces is corrugated in the form of nearly parallel optical elements having a common protective screen performing at the same time the function of their front surfaces and such that both surfaces of the transformer are in contact with a medium or media having a lower refractive index. The intended use of such diffuse light transformers is rooftop illumination of spaces, typically greenhouses, halls, living spaces, offices, corridors, collimating headlight optics, lighting, etc. Since maximum luminance in this case is absolutely essential the optical elements should be designed with total suppression of the primary escape-cone effect as described in this disclosure. Further, a diffuse light transformer need not be flat and for a range of reasons it may be convex or concave while the radius of curvature need not be uniform over the surface. Thus, the effective acceptance area of a transformer in view of more directional light sources can be increased by making its surface convex so that it accepts larger amounts of low altitude radiation, which is particularly essential for greenhouse applications. Equally so, the surface of the transformer may be designed to have a focal spot (or line) in view of headlight optics and the like. An optional antireflective coating is formed on the protective screen 610.

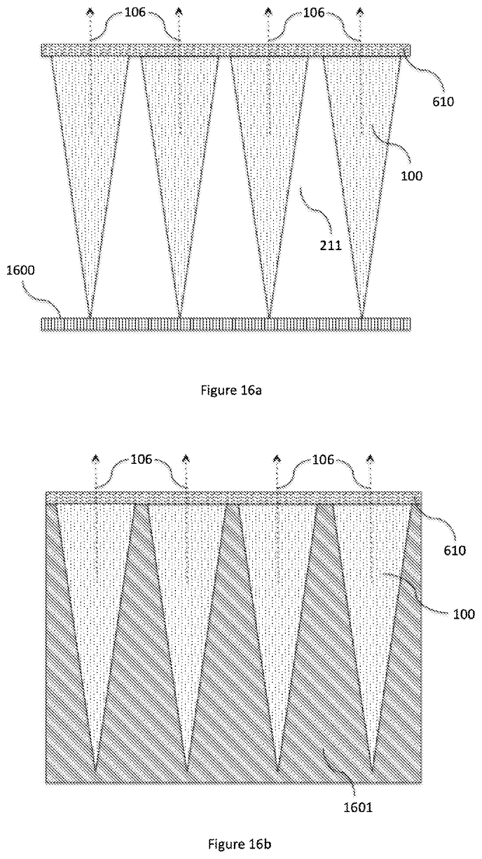

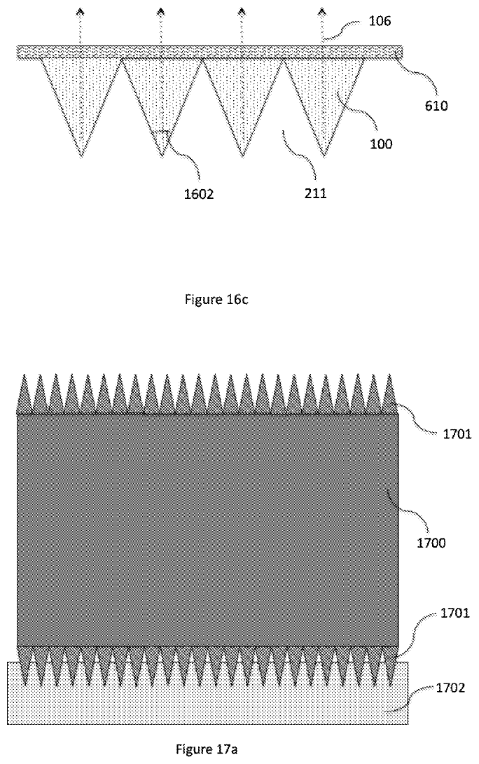

Diffuse light transformers can be designed in several ways as follows. In one design, as already illustrated in FIG. 15, the diffuse light transformer represents a sheet of transparent material comprising of at least one high refractive index material and where one surface is corrugated such that it comprises the peripheral and back surfaces of an array of optical elements with approximately parallel axes 106. One drawback of this design is that the corrugated surface is exposed to the environment which will eventually result in its contamination with dust leading to worsened performance with time. An improved design, as shown in FIG. 16a, includes a protective transparent sheet 1600, which protects the corrugated surface from the environment. The sheet 1600 is preferably made of a relatively low refractive index material to minimize reflection losses. A further improvement of this concept is presented in FIG. 16b where the corrugated surface of the transformer is filled with a relatively low refractive index optical material 1601, e.g. optically transparent aerogel, etc, and subsequently planarized.

A further design approach maximizes the quota of extrinsic rays as illustrated in FIG. 16c where the optical elements represent triangular prisms 1603 with an apex angle 1602 also denoted as α. Thus, in order to increase the quota of extrinsic rays the angle β (see eq. (4b) and ineq. (4c)) is chosen to be rather small. As an illustration we set β=0 leading to:

α/2=π/2−θ_{c} (19a)

Thus, the maximum divergence of extrinsic rays according to eq. (3b) is:

ψₑₓₜᵣ=θ_{c} (19b)

Eq. (19a), in fact, can be extended by setting β≤0, i.e.:

α/2≥π/2−θ_{c} (19c)

since if ineq. (19c) holds then ineq. (4a) holds too and, hence, the quota of extrinsic rays is still optimal. Thus, generally, the shape of the prism need not be triangular but most generally satisfies ineq. (19c), where the latter is interpreted as the slope (cot(α/2)) at an arbitrary point on a 2D cross-section of the prism 1603 in the frontal plane. Deviation from eq. (19a) in the context of ineq. (19c), however, leads to an increase in the spread of extrinsic rays. Intrinsic rays, on the other hand, are not guaranteed refraction. For low end applications this might be acceptable but generally for full transmission one needs to create an additional edge with a non-zero bandgap to guarantee proper refraction of intrinsic rays. This is done by sectioning of the prisms 1603 at regular intervals by creating, say, vertical separation gaps rotated about axis 106 at a specific angle thus forming an edge angle ζ with at least one exit-wall of the triangular prisms 1603 which satisfies ineq. (18b) and preferably eq. (14). Another way of guaranteeing the refraction of intrinsic rays is to introduce a more complex 3D topology. An example of this is where the triangular prisms are not straight prisms but rather undulating or zigzagging shapes. Other shapes are also admissible. The advantages of such a design are that a large fraction of the rays are extrinsic and hence they are refracted after the first collision with the exit-walls (design less sensitive to contamination). Not the least, the relatively large apex angle—see eq. (19a), allows simpler fabrication. For these reasons, this type of design represents a preferred embodiment of diffuse light transformers. Thus, this preferred embodiment in practical terms employs triangular prisms as optical elements having an apex angle given by eq. (19a) with a ±25% margin. A further suitable design is to choose the apex angle α of the triangular prisms to be close to the optimal angle given by eq. 14. In this case, a substantial fraction of intrinsic rays would be refracted upon the second collision with the exit-walls. In both cases sectioning of the prisms as described above is desirable to guarantee that all intrinsic rays are refracted.

The diffuse light transformer may be fabricated of the same materials as the optical elements in the diffuse light concentrator. Preferred embodiments include low cost optical materials such as glass, PMMA, PC and other polymeric materials in addition to optical liquids such as water in combination with alcohols, diols, flame retarding additives, aerogels, etc.

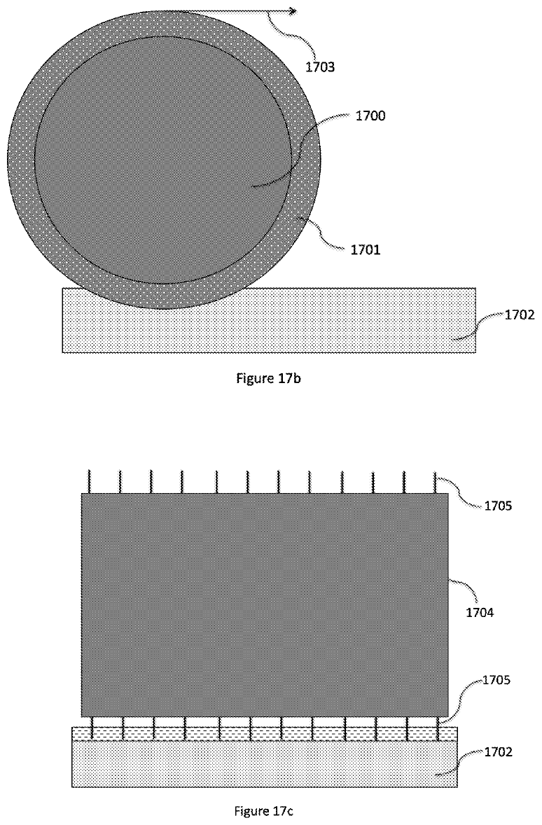

Diffuse light transformers may be fabricated in a number of ways as follows. FIG. 17a shows the cross-section of a roller wheel 1700 with parallel grooves 1701 such that the slope of the grooves satisfies ineq. (5b) or ineq. (18b) or any other design according to the present invention, including the one presented in reference to FIG. 16c above. The transparent sheet 1702 is heated to a suitable temperature to make it pliable after which the surface of the sheet is shaped in the form of triangular prisms by rolling the wheel 1700 along the surface as illustrated in FIG. 17b where arrow 1703 indicates the direction of roll in a side view. In the next step, a wheel cutter 1704 as illustrated in FIG. 17c is equipped with thin vertical knives 1705 and makes a rolling cut in a direction which generally concludes a non-zero angle with respect to the first rolling direction such that the resulting pyramidal sections acquire an angle between two neighboring walls satisfying ineq. (18b) and preferably eq. (14). The thickness of the knives 1705 is such that propagation of light in the resulting gaps satisfies geometrical optics, typically of the order of a few tens of micrometers unless other technological requirements impose other requirements. The density of knives 1705 is normally equal to that of the grooves of the roller cutter 1700 although this is not mandatory and can be optimized by various methods. Clearly, this is just one of many possible fabrication methods. Thus, one can employ embossing or any other similar method instead of the rolling forming above.

Another fabrication method is illustrated in FIG. 18. Specifically, it illustrates a mold 1800 (top) which represents the negative image of the desired corrugated surface and is optionally coated by a thin releasing layer. The mold 1800 is then filled (optionally under vacuum) with a monomer 1801 of the high refractive index material and subsequently polymerized. The form is then released and encapsulated on the corrugated side by a transparent carrier sheet 1802. To prevent the sheet from crushing by an external load separation spacers 1803 are simultaneously defined and evenly distributed throughout the sheet.

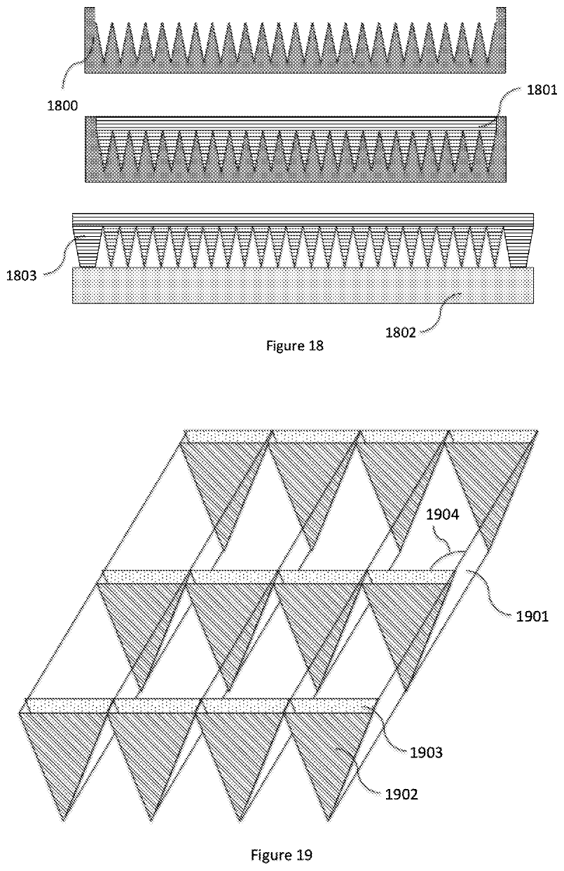

A further fabrication method, particularly suitable for the case in FIG. 16c owing to the relatively large apex angle, is illustrated in FIG. 19. Specifically, the triangular grooves 1901 are fabricated from a thin polymer sheet by thermoforming or another suitable method. The apex angle of the grooves is relatively large, preferably defined by eq. (19a). Separately, the spacers 1902 representing closed triangular (or other suitable shape) parallel wall prisms filled with a gas 1903 (air, nitrogen, argon, etc) are fabricated separately and arranged in an array. The latter is then inserted into the triangular grooves. Subsequently, the volume between the spacers is filled with an optical material such as water (in a mixture with anti-freezing agents) or a monomer followed by a polymerization step, or another optical material. The resulting structure is then optionally encapsulated from the top by a transparent protective screen. Needless to mention that the spacers are preferably rotated about axis 106 such that they form an angle with at least one exit-wall satisfying ineq. (18b) and preferably eq. (14), say, angle 1904 between the exit-wall 1901 and the neighboring face of the gap prism 1902. Optionally, the corrugated surface may be planarized with a low refractive index optical material. The thus fabricated sheets may also be provided with a self-adhesive coating allowing their mounting onto existing windows.

Clearly, the above descriptions are purely schematic and serve to illustrate several of many possible ways for the fabrication of diffuse light transformers.

### Examples/Results

In here we present some preliminary experimental and computational results in support of the present invention.
Triangular pyramids with a base 1×1×1 cm and a height of 15 cm have been fabricated of BK7 glass with a refractive index 1.5168 and density 2.51. The front surface (i.e. the base of the pyramid) was illuminated by a rastered laser beam under an angle of about 45 degrees. The resulting diffuse element image 300 has a circular form with a radius of about 1.5 cm.

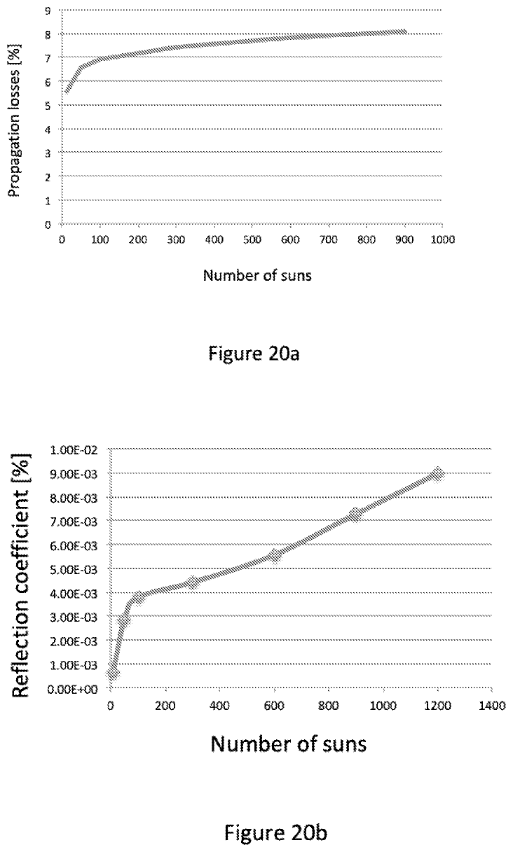

Further, a full ray tracing algorithm has been implemented based on the strict Fresnel formalism for both reflection/refraction at transparent interfaces as well as reflection off metal surfaces. The simulated concentrator consists of 96 triangular pyramids. The pyramids are made of an optical material with an assumed absorption coefficient of 0.004 cm⁻¹ and a refractive index of 1.333 and have the above dimensions, that is, 1×1×1×15 cm. The air gaps are assumed to have an absorption coefficient 0.0 and a refractive index 1.0. A comprehensive Monte Carlo ray tracing simulation is then performed where all input parameters such as incidence angle and position on the concentrator surface are randomly selected to render statistically meaningful results covering the whole surface and the full angular range of the incident light flux. The latter is assumed to have a uniform distribution in the solid angle 2π relative to the surface normal of any particular front surface. Only rays entering the concentrator through front surfaces have been traced since rays entering the concentrator through the air gaps experience no concentration and are not of interest. A total of 230400 rays were traced for each parameter combination. FIG. 20a shows the propagation losses in the concentrator as a function of the concentration coefficient. The statistically average propagation path is found to be approximately 1.5 times the pyramid height. FIG. 20b shows the rejection losses as a function of the concentration coefficient, i.e. intensity reflected back to the source. It is seen that the rejection losses are negligibly small indicating at the same time that they are solely due to the secondary escape-cone effect.

### REFERENCES

1. Cherney et al, U.S. Pat. No. 6,700,054 B2, Mar. 2, 2004
2. https://www.ise.fraunhofer.de/content/dam/ise/de/documents/publications/studies/Photovoltaics-Report.pdf
3. https://en.wikipedia.org/wiki/File:Fresnel power glass-to-air.svg

TABLE 1
Calculated divergence Ψᵢₙₜᵣ and Ψₑₓₜᵣ for a number of cases

| | | | | | Ψᵢₙₜᵣ | Ψₑₓₜᵣ |
|---|---|---|---|---|---|---|
| n₁ | n₂ | α [deg] | β [deg] | θ_{c} [deg] | [deg] | [deg] |
| 1.5 | 1 | 14 | 81.05 | 41.81 | 38.59 | 1.95 |
| 1.5 | 1 | 12 | none | 41.81 | 35.78 | none |
| 1.5 | 1 | 10 | none | 41.81 | 32.75 | none |
| 1.5 | 1 | 8 | none | 41.81 | 29.42 | none |
| 1.5 | 1 | 6 | none | 41.81 | 25.64 | none |
| 1.333 | 1 | 10 | 52.27 | 48.61 | 28.72 | 32.73 |
| 1.333 | 1 | 8 | 54.05 | 48.61 | 25.82 | 31.95 |
| 1.333 | 1 | 6 | 55.88 | 48.61 | 22.53 | 31.12 |
| 1.333 | 1 | 4 | 57.78 | 48.61 | 18.6 | 30.22 |
| 2.00 | 1 | 10 | none | 30.00 | 41.84 | none |

1. An optical system for concentrating incoming light in a predetermined wavelength interval comprising of a plurality of individual optical elements forming a body of optical elements, the individual optical elements comprising a front surface, a back surface, and a peripheral surface, wherein the peripheral surface extends from the front surface to the back surface, and wherein at least a portion of the individual optical elements are concentrating optical elements made of at least a first optically transparent material and for which the front surface is arranged to receive the incoming light, and the back surface and the peripheral surface are arranged to exit light, and wherein the area of the front surface area is larger than the area of the back surface of the same concentrating optical element, and wherein the concentrating optical elements are separated from adjacent individual optical elements by gaps extending in the directions of the peripheral surfaces, the gaps made of at least a second optically transparent material, the optical system further comprising:
an input acceptance aperture for receiving the incoming light, the input acceptance aperture formed by at least a major portion of the combined front surfaces of the individual optical elements;
an exit aperture for exiting light from the optical system, the exit aperture formed by at least a major portion of the combined back surfaces of the individual optical elements;
a boundary surface of the body of the optical elements formed by the outermost sections of the peripheral surfaces of the outermost optical elements; and
a reflective enclosure enclosing at least a portion of the boundary surface of the body of optical elements and provided with a reflective surface facing the enclosed body of optical elements,
wherein
the input acceptance aperture has a larger area than the exit aperture, and
the refractive index of the first optically transparent material of one concentrating optical element is higher than the refractive index of the second optically transparent material of at least one gap abutting the same one concentrating optical element.

2. The optical system according to claim 1, wherein each concentrating optical element is a polyhedron comprising a plurality of facets and wherein a first set of facets are facets belonging to the front surface, a second set of facets are facets belonging to the back surface and the peripheral surface of the concentrating optical element, and wherein the concentrating optical element has at least one pair of facets belonging to the second set of facets and comprising a first facet and a second facet, the first and the second facet arranged to be in direct visibility with each other and arranged with an internal angle, ζ, between the first and second facet of the pair of facets, the internal angle, ζ, selected to be in the interval
0<ζ<2.5a sin[n₂/n₁]
wherein n₁ is the refractive index of the concentrating optical element material, the first optically transparent material and n₂ is the refractive index of the gap material, the second optically transparent material, the refractive indices associated with the predetermined wavelength interval of the optical system.

3. The optical system according to claim 2, wherein the internal angle, ζ, between the first and second facet of the pair of facets is selected to be in the interval
0<ζ<2a sin[n₂/n₁]
and even more preferably in the interval
π/2−a sin[n₂/n₁]<ζ<2a sin[n₂/n₁].

4. The optical system according to claim 1, wherein the reflective enclosure comprises a first section with first reflective properties and at least a second section with second reflective properties.

5. The optical system according to claim 1, wherein the first section of the reflective enclosure comprises a metallic mirror and the second section comprises a Bragg mirror and wherein the first section is provided adjacent to the input acceptance aperture and the second section adjacent to the exit aperture.

6. The optical system according to claim 1, wherein the reflective enclosure is at least partly a layered structure wherein a first set of layers forms a metallic mirror and a second set of layers forms a Bragg reflector, the second set of layers provided on top of the first set of layers.

7. The optical system according to claim 1, wherein at least one concentrating optical element comprises a major sub-element and at least one minor sub-element, the major sub-element partly separated from the minor sub-element by at least one internal gap, the internal gap extending from the front surface in the direction towards the back surface but not extending all the distance to the back surface so that a portion of the concentrating optical element adjacent to the back surface is common to both the major sub-element and the minor sub-elements.

8. The optical system according to claim 7, wherein the refractive index of the material of the concentrating optical element is higher than the refractive index of the material in the internal gap.

9. The optical system according to claim 1, wherein the concentrating optical elements comprise a shell of a third optically transparent material defining the geometrical shape of the concentrating optical element and defining a cavity in the interior of the concentrating optical element and a filler of a fourth optically transparent material filling the cavity of the concentrating optical elements, and wherein the refractive index of the third optically transparent material is higher than the refractive index of the fourth optically transparent material.

10. The optical system according to claim 9, wherein the fourth optically transparent material is an optically transparent liquid comprising one of or a combination of water, alcohols, diols, and triols.

11. The optical system according to claim 1, wherein the optical system comprises a top protective transparent screen provided in contact with the combined front surfaces of the concentrating optical elements and spanning over the input acceptance aperture and joining the reflective enclosure at the circumference of the optical system.

12. The optical system according to claim 1, wherein the gap is filled with a gas.

13. The optical system according to claim 1, wherein the gaps between adjacent concentrating optical elements are defined by spacers of predetermined thicknesses, the spacers provided on the peripheral surfaces of at least a portion of concentrating optical elements.

14. The optical system according to claim 13, wherein at least a portion of the spacers are provided as protrusions from the peripheral surface of the corresponding concentrating optical elements.

15. The optical system according to claim 13, wherein the gap is defined by spacers comprising one part provided as a protrusion from a first concentrating optical element and a matching second part provided as a protrusion from an adjacent second concentrating optical element.

16-31. (canceled)
